(19) United States
(12) Patent Application Publication
(10) Pub. No.: US 2004/0075589 A1
(43) Pub. Date: Apr. 22, 2004

(54) Universal mobile keyboard

(76) Inventors: Lichen Wang, Watsonville, CA (US); Keming Yeh, Fremont, CA (US); Siew Ming Yong, Johor (MY)

Correspondence Address: Edward C. Kwok, MacPHERSON KWOK CHEN & HEID LLP, Suite 195E, 2001 Gateway Place, San Jose, CA, 95110, US

(21) Appl. No.: 10/631,942

(22) Filed: Jul. 30, 2003

Related U.S. Application Data
(63) Continuation-in-part of application No. 10/277,462, filed on Oct. 21, 2002.

(51) Int. Cl. H03M 11/00; H03K 17/94

(52) U.S. Cl. 341/22

(57) ABSTRACT

A versatile and mobile keyboard and an advantageous wireless data transmission method are provided. The keyboard may be used with a variety of mobile devices such as PDAs, cellular phones, and tablet PCs, through various interfaces such as an IR, USB, or Bluetooth™ interface. In particular, an IR head clamp assembly is provided that includes an IR head and a clamp body for attaching to a mobile device proximate the IR port of the mobile device. Advantageously, the IR head clamp assembly ensures high communication performance between the keyboard and the mobile device. The wireless data transmission method of the present invention is efficient and advantageously prevents erroneous characters from being displayed.

This patent application is a continuation-in-part of U.S. patent application Ser. No. 10/277,462, entitled “Universal Mobile Keyboard, attorney docket number M-15074 US, filed Oct. 21, 2002.

### BACKGROUND OF THE INVENTION

1. Field of Invention

The present invention generally relates to keyboards for mobile devices. More particularly, the present invention relates to a universal mobile keyboard including an infrared interface and an energy-efficient keyboard scanning method.

2. Discussion of the Related Art

Personal digital assistants (PDAs) have become more popular and affordable with improved technology, allowing for enhanced display quality, color richness, contrast, processing speed, power efficiency, memory capacity, RF communication capability, and other desirable characteristics. Similar advances are also made in other mobile devices, such as cellular phones, smart phones (PDA plus cellular handset), industrial data terminals, and tablet PCs. Thus, there is a growing need for an efficient and convenient universal device and method for data entry and for providing a user interface with these mobile devices.

Some mobile devices offer touch-sensitive LCD screens with built-in recognition software for data input by handwriting or “graffiti.” However, data input using graffiti is not convenient or efficient unless the user is properly trained in the method. Even then, data input using graffiti is not usually as fast as using a keyboard.

Some PDAs have built-in soft or virtual keyboards, or other input means, such as thumb-boards, silk-screen keyboards, and rubber keyboards. However, these input means are less efficient than small foldable keyboards that connect to the mobile device, such as a PDA, and offer the familiar desktop/notebook keyboard input style.

Such small foldable keyboards typically require a connector customized for each mobile device make or model. Usually a device-specific connector is used for both data exchange and for holding the mobile device in place. Such a connector often lacks stability, especially when typing with the keyboard on one's lap during, for example, convention seminars. Also, when a user gets a new mobile device, the user would also need to purchase a new keyboard. Some keyboards provide changeable connector heads. However, these changeable connector heads achieve only limited flexibility, given the many connector types that are used among mobile devices.

Since all major brands of mobile devices have built-in IR ports at various locations, wireless keyboards (e.g., infrared-based keyboards) are in high demand. However, typical infrared (IR)-based keyboards in the prior art suffer from several disadvantages. For example, a typical prior art IR keyboard uses a polished metal reflector to guide the IR beam from the keyboard to the IR port of a mobile device, which can be found at the top or at the side of the mobile device. Such a polished metal reflector is awkward to adjust and difficult to keep steady even on a desktop, not to mention on one's lap. Furthermore, to achieve the IR beam reflection, a stronger IR beam intensity than otherwise needed for data transmission is used. Thus, battery energy is inefficiently used, resulting in a shorter battery life or requiring a larger number of batteries (e.g., from 1 to 3 AAA batteries) or a higher battery capacity. In addition, a stronger than required IR beam intensity may in some instances (e.g., when well aligned and therefore having the maximum beam intensity) overwhelm or “blind” the IR receiver circuitry in a mobile device IR port, causing either data error or a sluggish response while waiting for the saturating effect to abate for each key stroke. A reflector-based IR beam guidance scheme has limited flexibility in aligning to IR ports, as the IR port may be found in any of a variety of possible locations on a mobile device.

Furthermore, the keys of a traditional keyboard may be split between “ordinary” keys and “context” keys. An ordinary key is one that may have one or more meanings; for example the “a” key means capital “A” when the “Shift” key is held down or when the “Caps Lock” key is in effect. The “a” key means lowercase “a” otherwise. A context key, when depressed, modifies the meaning of an ordinary key. Examples of a context key include a “Shift” key, a “Control” key, an “Alternate” key, a “Window” key, and an “Application” key. A subset of context keys are “lock” keys that can modify the meaning of an ordinary key but need not be held down. Instead, the effect of a lock key is like a toggle switch in which pressing the lock key once causes the lock key to be in effect and pressing the lock key again causes the lock key to no longer be in effect. Examples of a lock key include a “Caps Lock” key and a “Num Lock” key.

The traditional keyboard interface sends “scan code” whenever a key is pressed (“make”) or released (“break”). Based on the received make and break scan codes, the keyboard driver software inside the computer will track whether a context key is held down or not and whether a lock key is in effect or not and interpret the meaning of an ordinary key accordingly.

However, when infrared or other wireless interface is used, the keyboard transmission is subject to external interference resulting in several disadvantages. For example, external noise may be mistaken as real signals, real signals may be corrupted and interpreted incorrectly, and the keyboard driver inside the computer may lose track of the state of context keys and lock keys and interpret all subsequently pressed ordinary keys in the wrong context.

Therefore, what is needed is a keyboard for a mobile device that is operable with a large number of mobile devices. In particular, a keyboard with an IR interface is needed that is operable with and adjustable for a variety of possible IR port locations found on various mobile devices. Additionally, a keyboard scanning method is needed that is highly energy efficient to increase battery life and improve keyboard portability. Furthermore, a wireless data transmission method is needed to overcome external interferences.

### SUMMARY

The present invention provides a universal keyboard that includes multiple interfaces for operability with a variety of mobile devices, such as PDAs, smart telephones, and cellular telephones. Furthermore, advantageous methods are provided for interfacing with a mobile device in communication with a keyboard and for transmission of wireless data.

According to one aspect of the present invention, a method is provided whereby software is downloaded from a storage medium in the keyboard to a mobile device without having to place the mobile device in a cradle or a docking device attached to a desktop computer or a notebook computer.

According to another aspect of the present invention, an advantageous wireless data transmission method is provided. The wireless data transmission method includes providing a first data segment and verifying that the first data segment is a desired constant. A variable second data segment is also provided to indicate making a key or breaking a key. A third data segment is provided as necessary as a context code, and a fourth data segment is provided as necessary for an error check of the second and third data segments.

According to another aspect of the present invention, a method for interfacing with a mobile device in communication with a keyboard is provided. The method includes providing in the keyboard a communication interface for establishing a communication link with a mobile device, providing a plurality of storage access devices for writing data to storage media, and providing a controller coupled to the communication interface and the plurality of storage access devices. The controller is programmed to retrieve from the mobile device data to be synchronized using the communication interface, and send the data to be synchronized to the plurality of storage access devices using the controller.

According to another aspect of the present invention, a method for interfacing between mobile devices in communication with a keyboard is provided. The method includes providing in the keyboard a plurality of communication interfaces for establishing a communication link with a plurality of mobile devices, and providing a controller coupled to the plurality of communication interfaces, the controller being programmed to synchronize data between the plurality of mobile devices using the plurality of communication interfaces.

According to another aspect of the present invention, a universal keyboard includes a docking structure for accommodating a mobile device, and an infrared (IR) head clamp for receiving and transmitting data over a wireless link, the IR head clamp capable of being positioned over an IR port of the mobile device. The universal keyboard further includes a keypad that is physically coupled to the docking structure and provides electrical signals representing the keys on the keypad that are depressed by an external agent. A controller circuit receives the electrical signals and converts the electrical signals into data for transmission by the IR head clamp over the wireless link.

According to another embodiment of the present invention, a universal keyboard includes an arm having a first end mounted on the docking structure at one end by a connector, and having a second freely movable end. The second freely movable end of the arm traces an arc centered about the connector over a predetermined range of angles. An infrared (IR) head is mounted on the freely movable end of the arm for receiving and transmitting data over a wireless link.

According to another embodiment of the present invention, a keyboard includes a communication interface for establishing a communication link with a mobile device, a storage access device for retrieving data from and writing data to a storage medium, and a controller coupled to the communication interface and the storage access device. The controller is programmed to retrieve identification information from the mobile device using the communication interface, and according to the identification information, retrieve from the storage medium a program code. The controller is then programmed to transmit to the mobile device the program code using the communication interface.

The present invention allows for great flexibility in transmitting data to an IR port located at any of many positions on a mobile device while also providing highly efficient methods for interfacing between mobile devices, keyboards, and storage media.

These and other features and advantages of the present invention will be more readily apparent from the detailed description of the embodiments set forth below taken in conjunction with the accompanying drawings.

### BRIEF DESCRIPTION OF DRAWINGS

FIGS. 1A-1D show different views of an unfolded universal keyboard in accordance with an embodiment of the present invention.

FIGS. 2A-2D show different views of an unfolded universal keyboard with an example of a docked PDA in accordance with an embodiment of the present invention.

FIG. 3 shows an unfolded universal keyboard with an example of a docked cellular telephone in accordance with an embodiment of the present invention.

FIG. 4 shows an unfolded universal keyboard operably coupled to an example of a docked tablet PC in accordance with an embodiment of the present invention.

FIGS. 5A-5B show an unfolded universal keyboard in accordance with another embodiment of the present invention.

FIGS. 6A-6B show the outer surface of the folded universal keyboard of FIGS. 5A-5B in accordance with an embodiment of the present invention.

FIG. 6C shows a docking structure, IR head, arm structure, and connector of the universal keyboard of FIGS. 5A-5B in accordance with an embodiment of the present invention.

FIGS. 7A-7C show different views of the outer surface of a folded universal keyboard, IR head, arm, and connector in accordance with another embodiment of the present invention.

FIG. 8 shows an example of a foldable keyboard with a locking mechanism in accordance with an embodiment of the present invention.

FIGS. 9A-9C show a central hinge of a universal keyboard in accordance with an embodiment of the present invention.

FIGS. 10A-10B show a central hinge of a universal keyboard in accordance with another embodiment of the present invention.

FIG. 11 shows an example a mouse or cursor selector in accordance with an embodiment of the present invention.

FIGS. 12A-12B show different views of a folded universal keyboard with a top cover in accordance with an embodiment of the present invention.

FIG. 13 shows an example of an inside surface of a top cover that is capable of holding various cards and memory devices.

FIG. 14 shows an example of an IR, USB, or Bluetooth™ interface selector in accordance with an embodiment of the present invention.

FIG. 15 shows an example of a universal keyboard circuit diagram in accordance with an embodiment of the present invention.

FIG. 16 shows an adaptor for a USB interface, according to one embodiment of the present invention.

FIG. 17 shows an adaptor for a Bluetooth™ interface, according to one embodiment of the present invention.

FIG. 18 shows Circuit 1800 suitable for implementing switching between battery power (IR interface) and a serial or USB interface.

FIGS. 19A and 19B show an IR head assembly and a device holding surface in accordance with another embodiment of the present invention.

FIG. 20 shows an IR head clamp assembly in accordance with another embodiment of the present invention.

FIGS. 21A-21C show an IR arm connector in accordance with an embodiment of the present invention.

FIG. 22 shows a flowchart of a wireless data transmission method in accordance with an embodiment of the present invention.

FIGS. 23A-23B show an IR arm connector in accordance with another embodiment of the present invention.

Use of the same reference symbols in different figures indicates similar or identical items. It is further noted that the drawings may not be drawn to scale.

### DETAILED DESCRIPTION

The present invention provides a universal keyboard that can be used with any of a variety of mobile devices, such as PDAs, cellular/smart phones, and tablet PCs. The present invention also provides a universal and highly energy efficient keyboard.

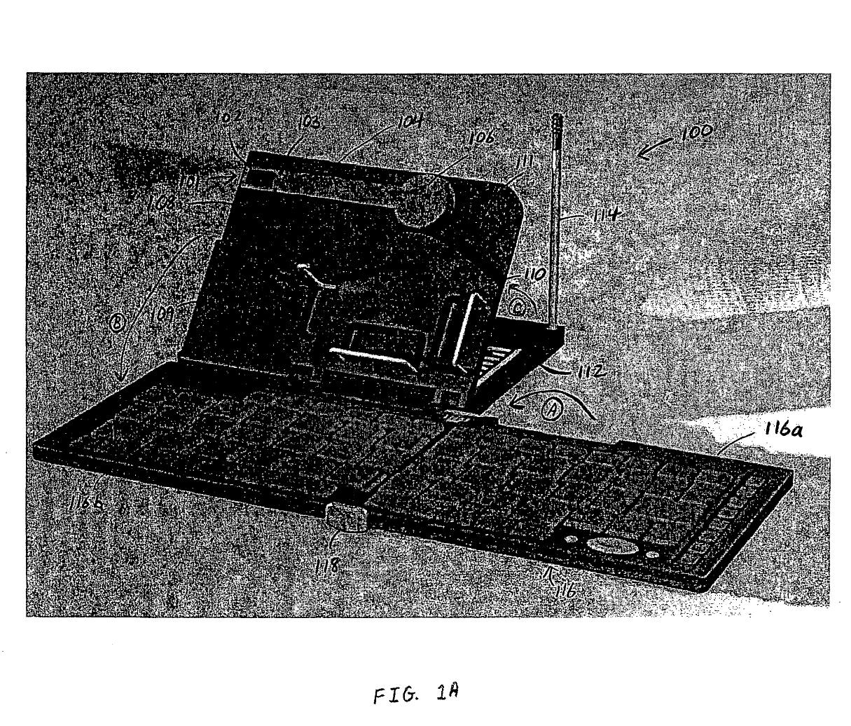

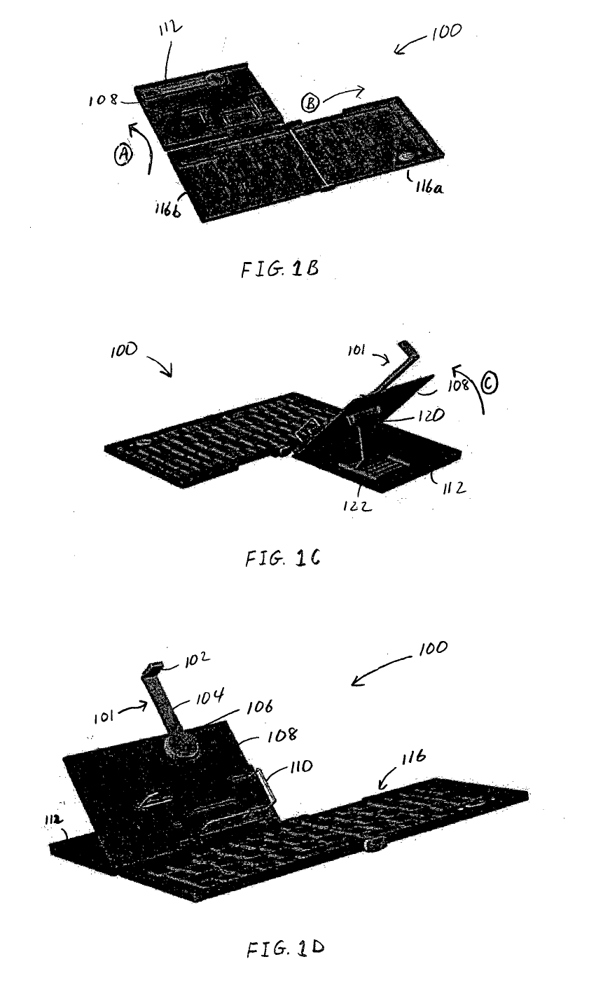

FIGS. 1A-1D illustrate an unfolded universal keyboard 100, in accordance with one embodiment of the present invention. As shown in FIGS. 1A-1D, an infra-red (IR) head assembly 101 is mounted on a docking structure 108, which is attached to keypad 116. Top cover 112 may also optionally be included with universal keyboard 100.

In one embodiment, IR head assembly 101 includes IR head 102, which is mounted on an arm 104 that is rotatable about an axis perpendicular to a plane of docking structure 108, and connector 106. IR head 102 includes an IR light emitting diode (LED). In one embodiment, the LED is biased to conduct an electrical current that provides an IR beam intensity calculated to achieve a high IR signal-to-noise ratio and a small IR data error rate, based upon an estimation of the minimum and maximum distances between IR head 102 and an IR port of a mobile device that can be mounted on the docking structure 108. In one implementation, the minimum and maximum IR beam distances are determined to be about 0.3 cm and about 3 cm, respectively. In that implementation, using a commercially available IR LED Vishay TSMF1000, the electrical current supplied to the IR LED may range between about 2 mA to about 10 mA. Alternatively, multiple LEDs, a single wide-angle LED, or an integrated transceiver module consisting of an LED emitter, an IR transceiver, and a positive-intrinsic-negative (PIN) diode detector, may be used to cover wider angles for transmission and optionally, reception of data to and from the IR port of the mobile device.

IR head 102 may be mounted on arm 104 by a hinge 103 or other suitable mechanism in order to enable IR head 102 to be positioned at any of a range of angles relative to arm 104 (FIGS. 1C and 1D).

In accordance with one embodiment of the present invention, IR head 102 is mounted on arm 104 by a joint 1910, as illustrated in FIGS. 19A and 19B. Joint 1910 allows IR head 102 to bend and/or rotate in multiple angles with respect to arm 104, such as allowing IR head 102 to bend in multiple angles substantially perpendicular to the length-wise axis of arm 104 and/or to rotate along the length-wise axis of arm 104. Such movement can be accomplished by a universal joint for example. In another example, joint 1910 includes a ball-and-socket joint or a tube swivel joint.

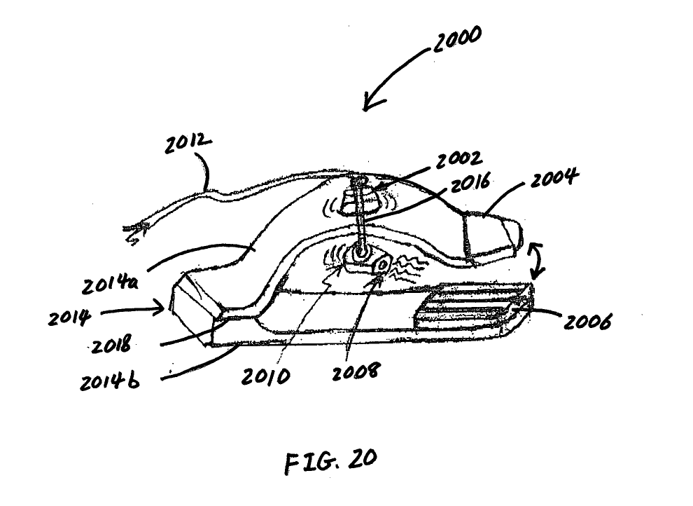

In accordance with another embodiment of the present invention, an IR head is not mounted on an arm but is coupled to a clamp body to form an IR head clamp assembly 2000, as illustrated in FIG. 20. IR head clamp assembly 2000 includes an IR head 2008 operably coupled to a clamp body 2014. Advantageously, IR head clamp assembly 2000 is capable of positioning the IR head proximate to the IR interface of the mobile device by physically clamping onto the mobile device.

In one example, IR head 2008 is operably coupled to clamp body 2014 via a universal joint 2010 (such as a ball-and-socket joint) and a swivel joint 2002, with a rod 2016 coupling the joints. Advantageously, universal joint 2010 and swivel joint 2002 allow IR head 2008 great flexibility in movement for clear and direct line-of-sight transmission and reception of data to and optionally, from the IR port of the mobile device. Other applicable joints may be used to operably couple IR head 2008 to clamp body 2014 that allows for flexibility of movement relative to clamp body 2014. In one example, IR head 2008 is capable of being moved vertically up and down along rod 2016 (i.e., moving along the length-wise axis of rod 2016) by a screw or slide mechanism or other suitable structure.

IR head 2008 includes a light emitting diode, a plurality of light emitting diodes, or optionally, an integrated infrared transceiver and otherwise functions in similar manner to the other embodiments of the IR head detailed above. A wire 2012 operably couples IR head 2008 to keypad 116 and/or a power source.

As further illustrated in FIG. 20, clamp body 2014 includes a first member 2014a coupled to a second member 2014b. In this example, first member 2014a is shaped to include an arc to provide space for coupled IR head 2008 and to provide clamping force with sufficient elasticity to allow for expandable opening of the free ends to accommodate the thickness of the mobile device edge where the IR port is located. Second member 2014b is substantially shaped as a flat structure, with both members having substantially flat areas near their free ends. Note that first member 2014a and second member 2014b may have other shapes that can provide space for the coupled IR head and allow for expandable opening and clamping functions of the free ends. For example, second member 2014b may also be shaped to include an arc with a flat area near a free end or both members of clamp body 2014 may have rectangular step-like features.

First member 2014a and second member 2014b may move apart and together along a joint 2018 such that free ends of first member 2014a and second member 2014b can move in directions shown by the double-arrowed arc. Accordingly, the free ends of first member 2014a and second member 2014b of clamp body 2014 may clamp onto a mobile device to position IR head 2008 proximate the IR interface of the mobile device.

In one example, first member 2014a and second member 2014b are simply connected together by an adhesive or are manufactured as a unitary molded structure. In this case, first member 2014a and/or second member 2014b may be made of a flexible plastic or elastomer such that the members of clamp body 2014 may flex open and closed, allowing for the clamping function.

In another example, joint 2018 may include hinge joints, universal joints, or other applicable joints with sufficient bias that allow the free ends of first member 2014a and second member 2014b to clamp onto objects without slipping. In a further example, first and second members of clamp body 2014 may be formed of malleable materials that have a shape memory to allow clamp body 2014 to clamp onto objects without slipping.

In another example, portions of the free ends of first member 2014a and second member 2014b may include grip sections 2004 and 2006 that are grooved or formed of a non-abrasive elastomer, such as Teflon, to aid the clamping process and prevent slipping without damaging the mobile device.

Referring back to FIGS. 1A-1D, arm 104 is mounted on docking structure 108 by connector 106 (e.g., a ball bearing, gear, or spring/coil structure) that allows arm 104 to rotate around an axis perpendicular to a plane of docking structure 108, and optionally, to sit in a groove and spring upward relative to docking structure 108. The location of connector 106 and the length of arm 104 are selected to allow IR head 102 to be positioned for line-of-sight communication with an IR port of any of a large number of mobile devices that can be mounted on docking structure 108, regardless of their IR port locations. To ensure a consistent electrical current to IR head 102 regardless of the position of rotatable arm 104 and to maintain a relatively thin structure, a circular multi-hub copper contact structure and/or a stretchable electric wire in the form of a coil or spring is included in connector 106. In one example, arm 104 has a length of about 8 cm. In addition, in one implementation, one or more batteries that are housed in arm 104 power IR head 102.

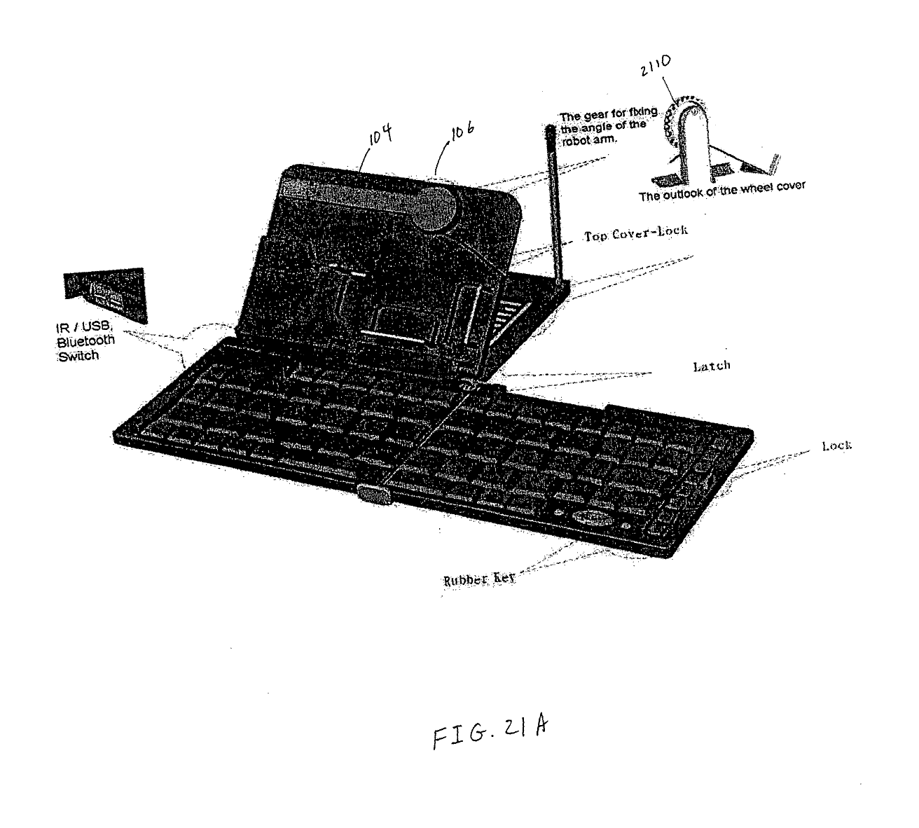

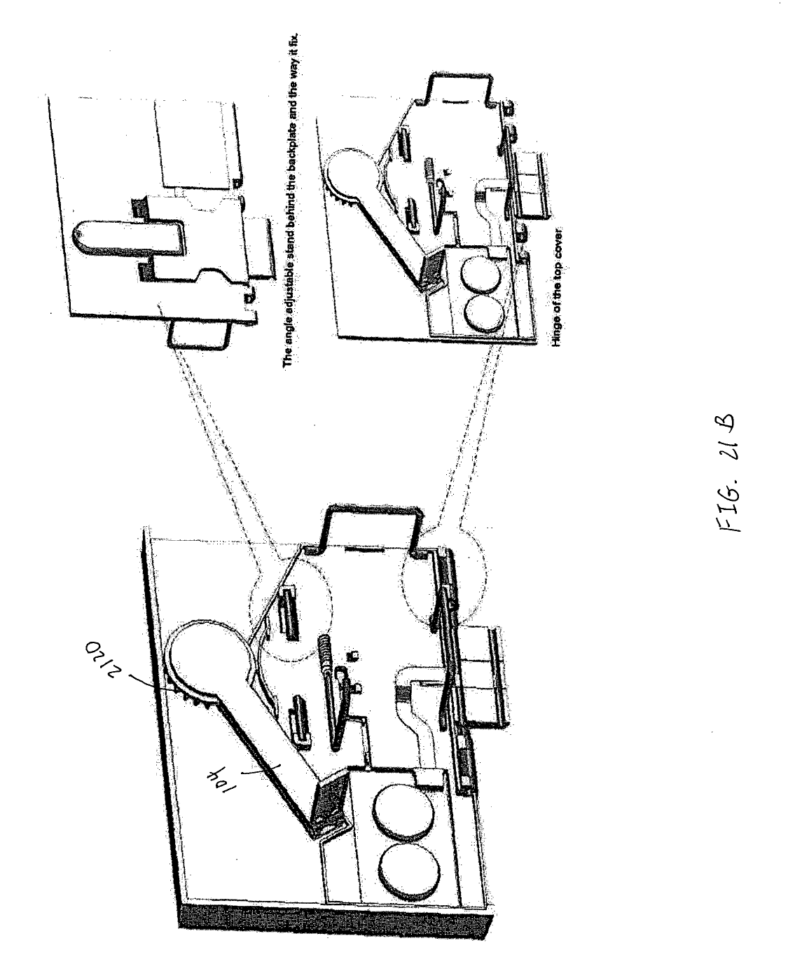

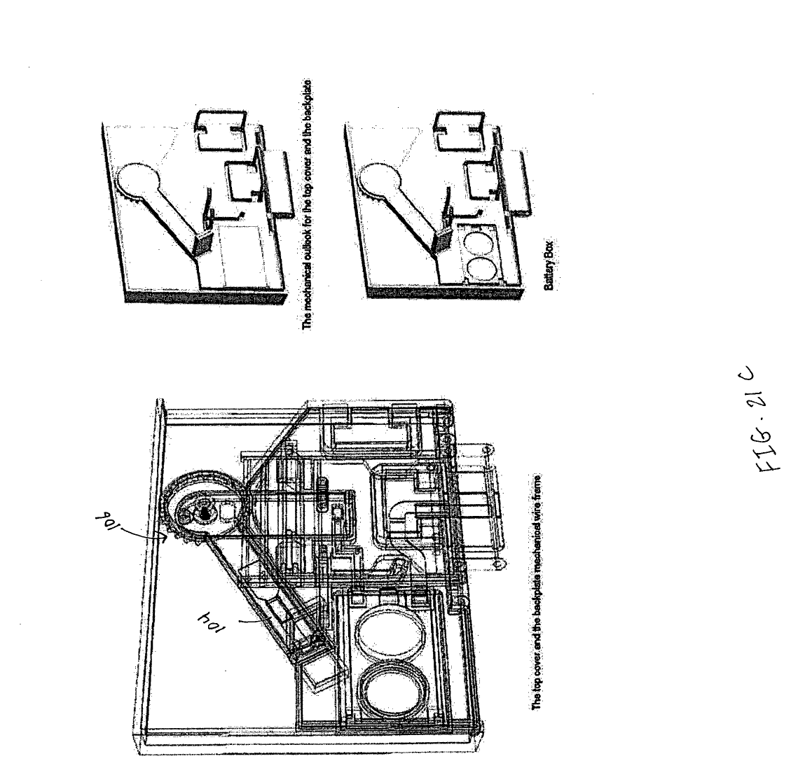

FIGS. 21A-21C show different views of an example of a connector 106 in accordance with the present invention. In order to allow arm 104 to be set at desired angles, connector 106 includes, in one example, a gear structure 2110 (FIG. 21A) that operates in conjunction with teeth 2120 (FIG. 21B). In one example, gear structure 2110 and teeth 2120 both include triangular teeth. Teeth 2120 operably fit in the gaps between the teeth of gear structure 2110 and likewise, the teeth of gear structure 2110 operably fit in the gaps between teeth 2120 such that at each increment of either the teeth of gear structure 2110 or teeth 2120, an angle for arm 104 may be set. Teeth 2120 are finely-incremented and sharp to allow for freedom and precision in setting of angles for arm 104. In a further example, gear structure 2110 and teeth 2120 are made of hard plastic that resist rounding of the teeth, which can lead to slipping from the desired angle. Gear structure 2110 and teeth 2120 may be made from different materials having similar durability and formation.

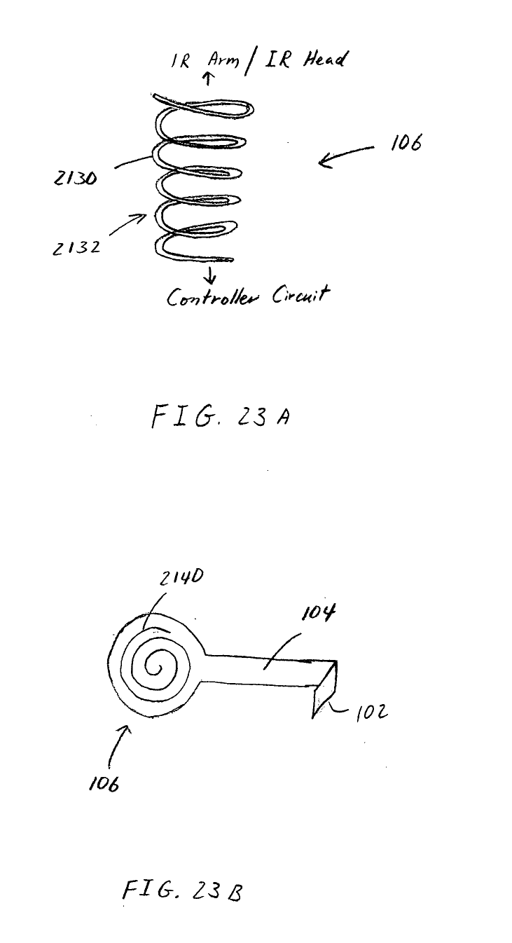

FIGS. 23A-23B show different views of another example of a connector 106 in accordance with the present invention. In this example, an electrical wire 2130 of sufficient thickness and rigidness to maintain the shape of a coil or spring 2132 is used within a housing to ensure a consistent electrical current to IR head 102 regardless of the position of rotatable arm 104. One end of electrical wire 2130 or one end loop of coil 2132 is in electrical contact with IR head 102 and the other end of electrical wire 2130 or the other end loop of coil 2132 is in electrical contact with a controller circuit of the keyboard. In one example, the coil or spring can stretch while arm 104 is turned to a maximum rotation, and the coil or spring can flex back to its initial state upon the return of arm 104 to a rotational starting position. FIG. 23B shows a schematic of a top view of connector 106 in which an electrical wire 2140 is formed into a coil having a tapering radius on one end. It will be evident that coils of different radii and shape may be used within the present invention to maintain electrical contact with IR head 102 while arm 104 is rotated.

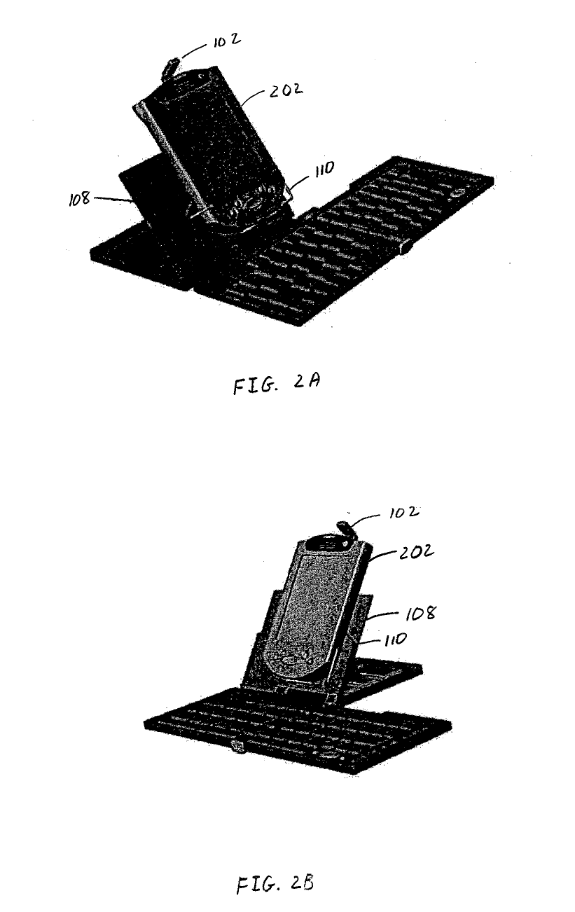

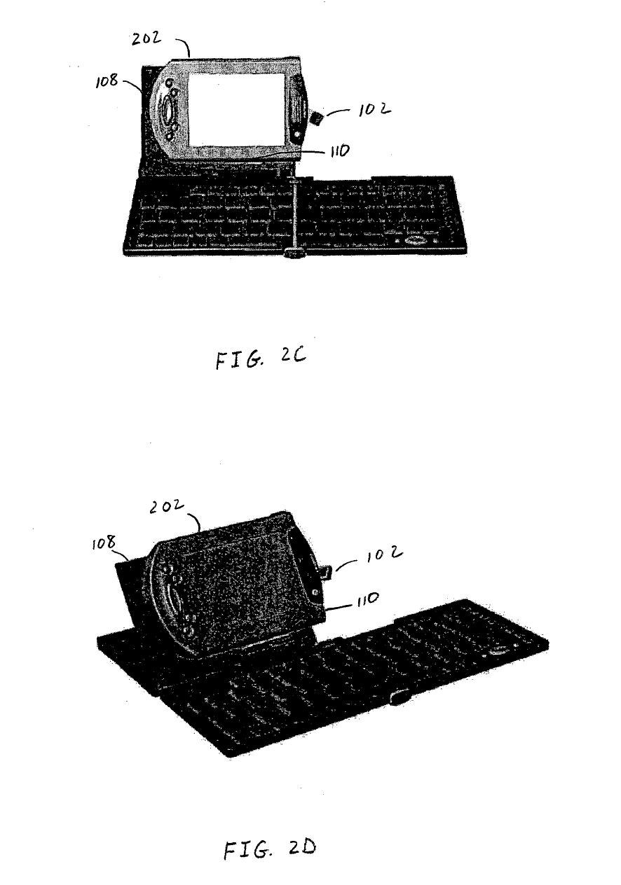

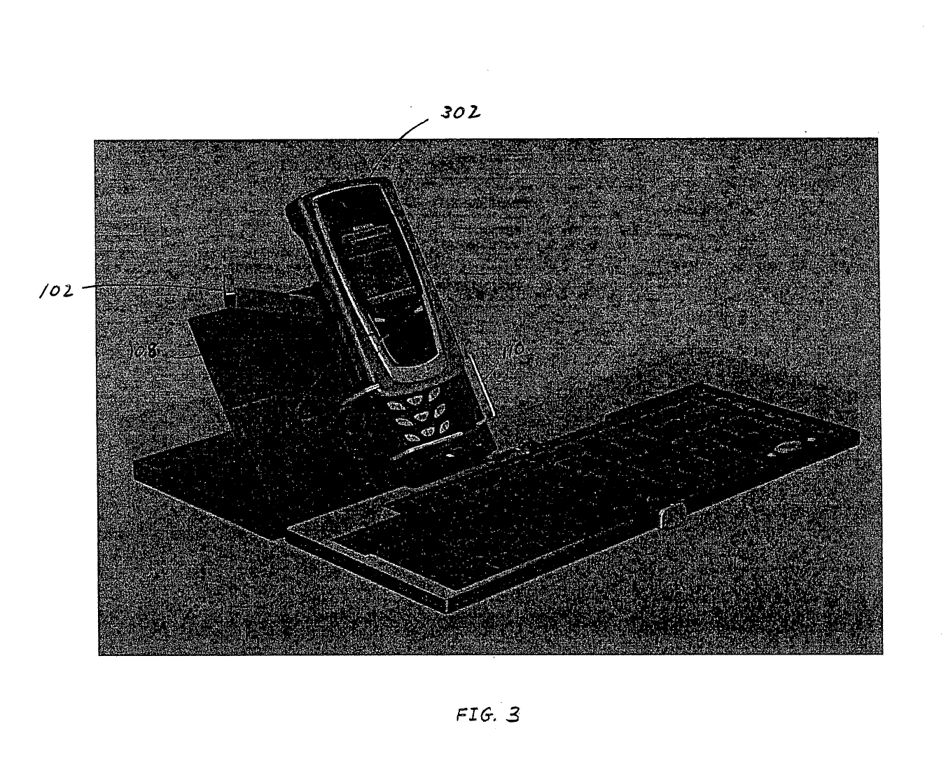

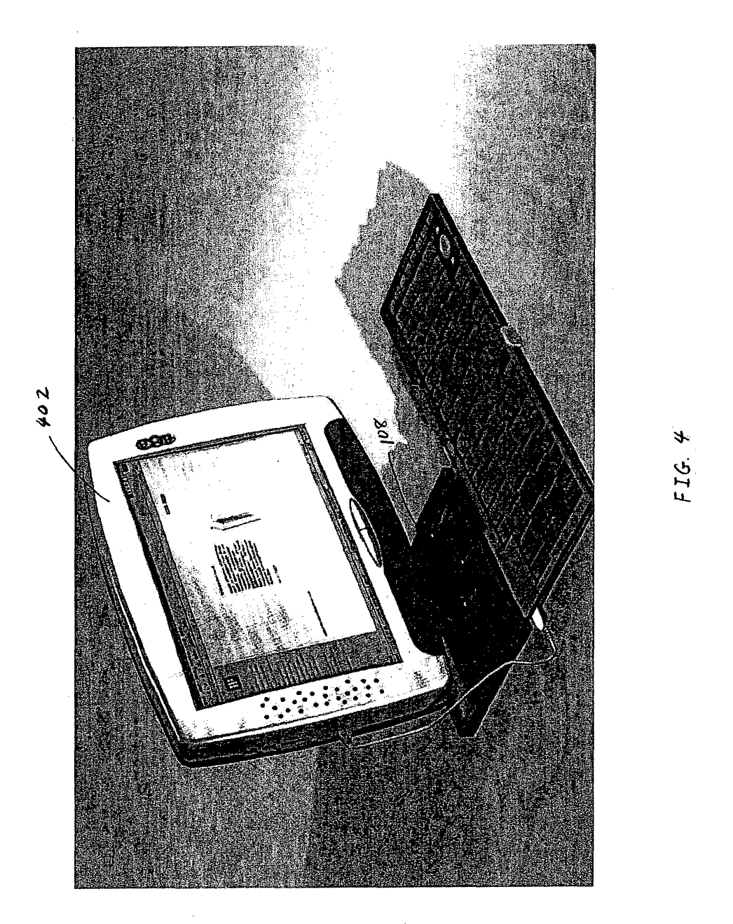

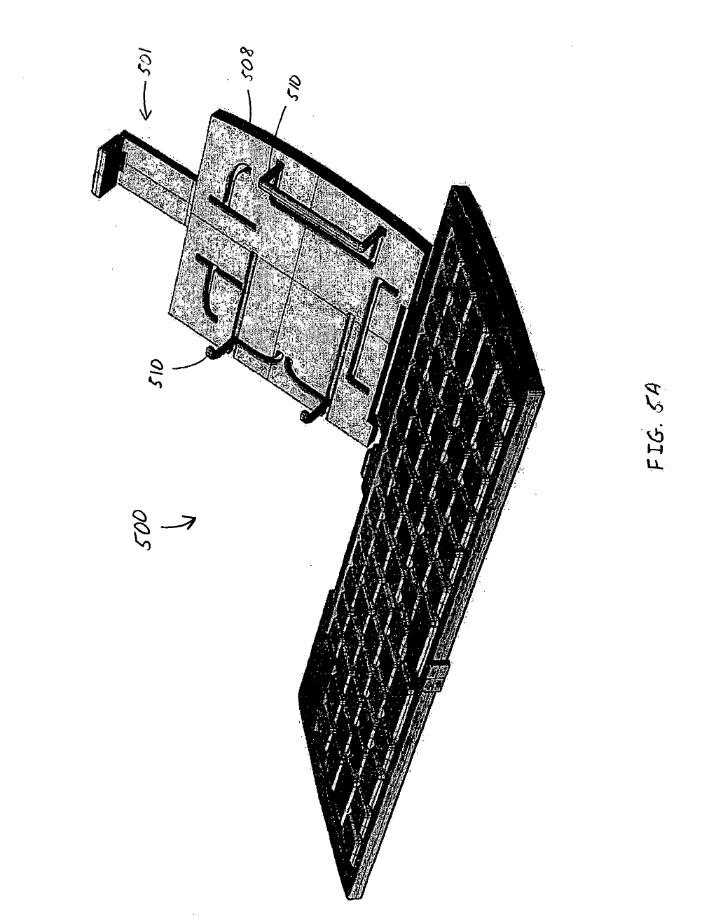

In one embodiment, docking structure 108 includes spring-loaded movable device holders 110 for securely holding in place a mobile device (e.g., a PDA, a smart phone, or a tablet PC) oriented in one of many possible orientations, such as shown in FIGS. 2A-2D, 3, and 4. FIGS. 2A-2B show a PDA 202 securely docked in a “portrait” position on docking structure 108 and FIGS. 2C-2D show a PDA 202 securely docked in a “landscape” position on docking structure 108. FIG. 3 shows a cellular phone 302 securely docked on docking structure 108 and FIG. 4 shows a tablet PC 402 securely docked on docking structure 108.

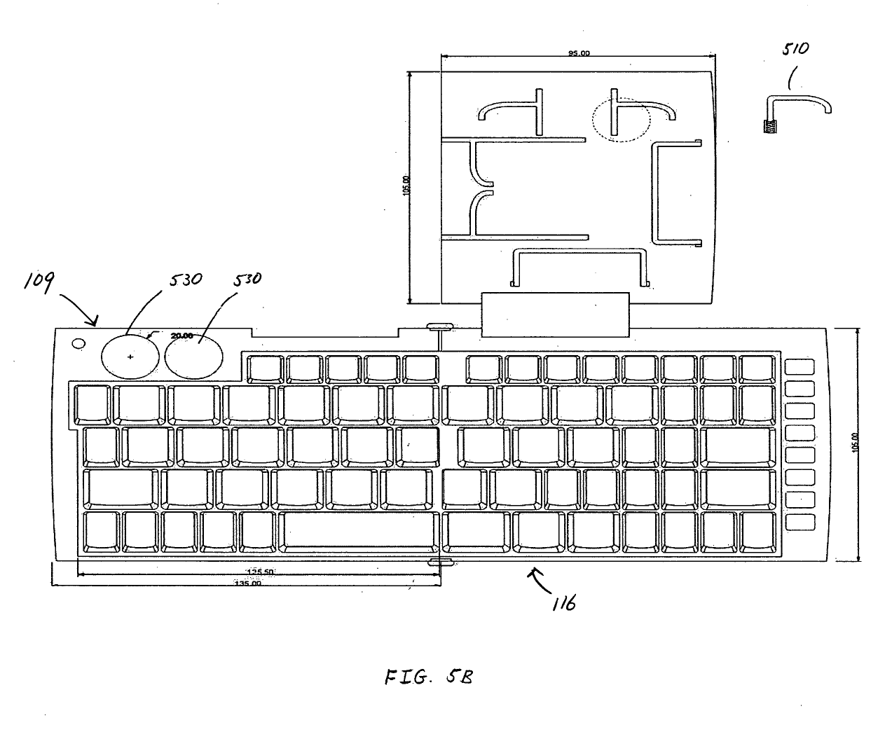

As noted above, a prior art connector-based keyboard uses the connector to hold the mobile device in place, often resulting in an unstable configuration. By contrast, holders 110 are designed and positioned to secure onto docking structure 108 any of a large number of mobile devices of various lengths, widths, and thicknesses. Grooves into which holders 110 may be folded or retracted are provided on one surface of docking structure 108 (FIG. 1B). Holders 110 are designed to be flush with the surface of docking structure 108, when folded or retracted into the grooves. Holders 110 need to be placed and/or shaped only as shown in FIGS. 1A-1D. Holders 110 may be placed in various positions and formed into various shapes with corresponding grooves to securely hold a mobile device. Holders 110 may be made of metallic or rubber material. It is also advantageous to cover metallic holders with a rubber coating to avoid damage of the mobile device body where holders grip the mobile device. A rubber coating also advantageously prevents slipping. FIGS. 5A-5B illustrate examples of other spring-loaded holders 510 that may be used in accordance with the present invention.

Referring now to FIGS. 19A and 19B, a surface 1920 and/or a surface 1924 is provided for mounting mobile devices onto docking structure 108. In some cases, a mobile device may be too tall and cannot fit well between a bottom holder and the IR head 102 on the IR arm 104. More clearance in the vertical dimension may be needed. In accordance with the present invention, anti-skid surface 1920 between docking structure 108 and keypad 116 is used to mount the mobile device. In this embodiment, the bottom holder would not be used but put in the retracted position.

Surface 1920 is located between docking structure 108 and keypad 116. In one embodiment, surface 1920 is a top surface of a hinge structure coupling docking structure 108 and keypad 116 and lies substantially flat between docking structure 108 and keypad 116 when the keyboard is in an opened position. In another embodiment, surface 1920 includes at least one raised projection 1922 and preferably includes raised projections 1922 to provide traction for a device positioned to rest on surface 1920 and docking structure 108. Raised projections 1922 must fit in a gap between the folded halves of keypad 116 and in one example has a height of about 2 mm. In yet another embodiment, surface 1920 may be anti-skid or rubber padding to securely mount the mobile device bottom without slipping.

In other cases, it is possible that a mobile device body is too narrow and holders 110 may not be sufficiently movable to mount both narrow and wide mobile devices. Accordingly, another structure may be required to hold a mobile device in place.

Surface 1924 is located on docking structure 108 substantially between holders 110 and can contribute to holding a narrow mobile device in the upright position. Surface 1924 can include padding (e.g., anti-skid padding, or rubber padding) to provide traction for the mobile device on docking structure 108.

When surface 1920 and/or surface 1924 are utilized for mounting a mobile device, holders 110 will need to be appropriately retracted or positioned to properly and securely mount the mobile device to surface 1920 and docking structure 108. In one embodiment, holders 110 may all be retracted and only surface 1920 and surface 1924 of docking structure 108 may be used to mount the mobile device.

In one embodiment as further shown in FIGS. 1A-1D, docking structure 108 includes a recessed area 111 on an inside surface of docking structure 108 at which connector 106 connects to IR head assembly 101. Recessed area 111 allows the arm structure of IR head assembly 101 to freely move through a large range of angles when a mobile device is docked, and provides the universal keyboard a thin profile when docking structure 108 is in the folded position for storage or travel.

Alternatively, IR head assembly 101 may be mounted on an outer surface of docking structure 108 to enable more holders or holder structures to be provided on the inside surface of docking structure 108, such that a greater number of mobile devices of various shapes and sizes can be held by docking structure 108 in a variety of positions (e.g., in portrait or landscape positions).

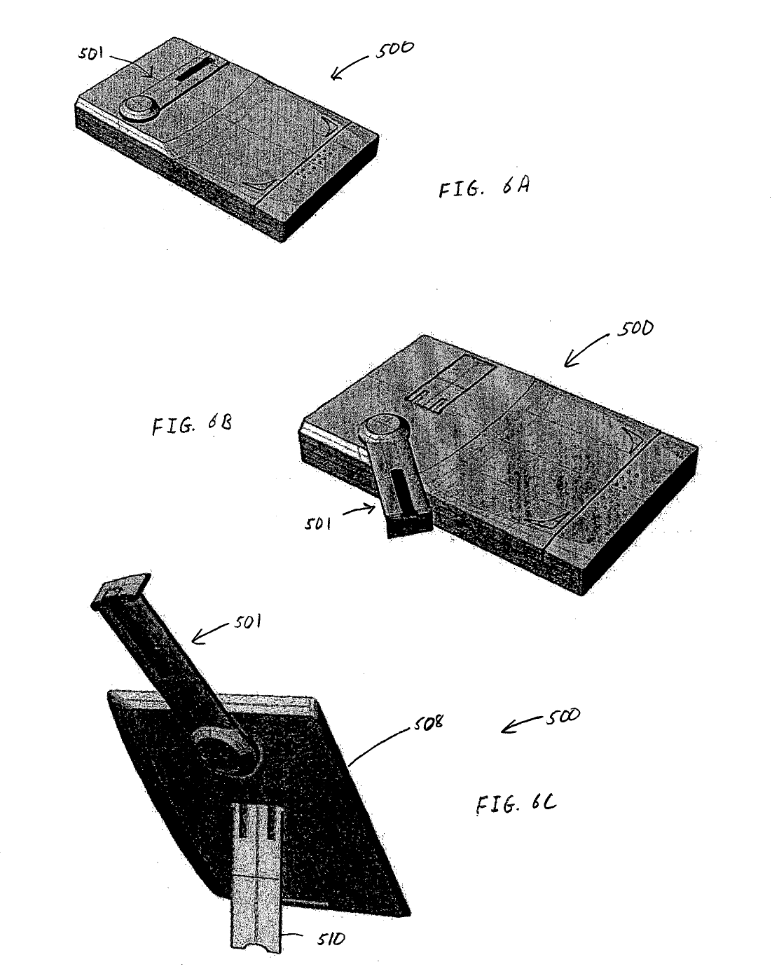

FIGS. 5A and 6A-6B show an IR head assembly 501 that is provided on an outer surface of docking structure 508, with a recessed area into which IR head assembly 501 can be secured when the IR keyboard 500 is in the folded, or storage/travel position. In that configuration, the properly secured IR head assembly 501 is substantially flush with the outer surface of docking structure 508.

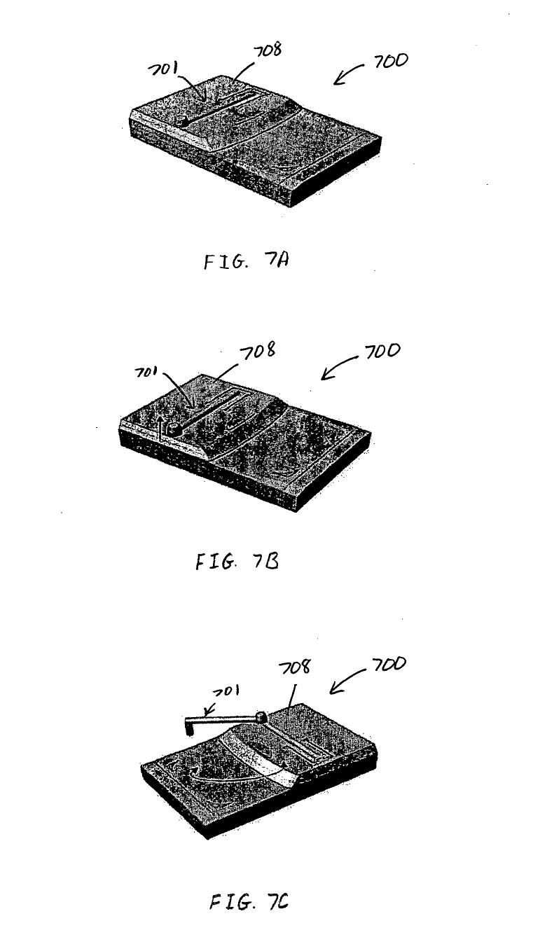

FIGS. 7A-7C show IR keyboard 700, according to another embodiment of the present invention, in which IR head assembly 701 is mounted by a spring-loaded mechanism to an outer surface of docking structure 708. IR head assembly 701 may be placed within a recessed area of the outer surface of docking structure 708 in the storage or folded position (FIG. 7A). IR head assembly 701 can be lifted up from the recessed area (FIG. 7B), and be allowed to move freely along a circular arc that is parallel to the surface of docking structure 708 (FIG. 7C) and centered about an axis perpendicular to docking structure 708.

Referring back to FIG. 1C, docking structure 108 may also include stand 120 which is attached to the outer surface of docking structure 108. Stand 120 may be slotted into any one of several grooves 122 provided on the inner surface of top cover 112, such that docking structure 108 can be supported at various inclined angles relative to the surface of top cover 112. Alternatively, stand 120 may be made free-standing at one of various inclined angles on the flat surface on which IR keyboard 100 is unfolded. FIG. 6C shows IR keyboard 500 having stand 510 supporting an outer surface of docking structure 508 at various inclined angles relative to the surface on which keyboard 100 is placed. This may be accomplished by gear structures at the joining and supporting points of stand 510 with docking structure 508. Alternatively, referring back to FIG. 1C, stand 120 may be attached to top cover 112 and may be coupled into any one of several grooves formed into an outer surface of docking structure 108.

Docking structure 108 may also include battery compartment 109 to hold one or more batteries used for providing power to IR head 102. Of course, battery compartment 109 need not be placed in docking structure 108 but may also be placed in keypad 116 instead. FIG. 5B shows batteries 530 being placed in battery compartment 109 provided at the upper left hand corner of keypad 116.

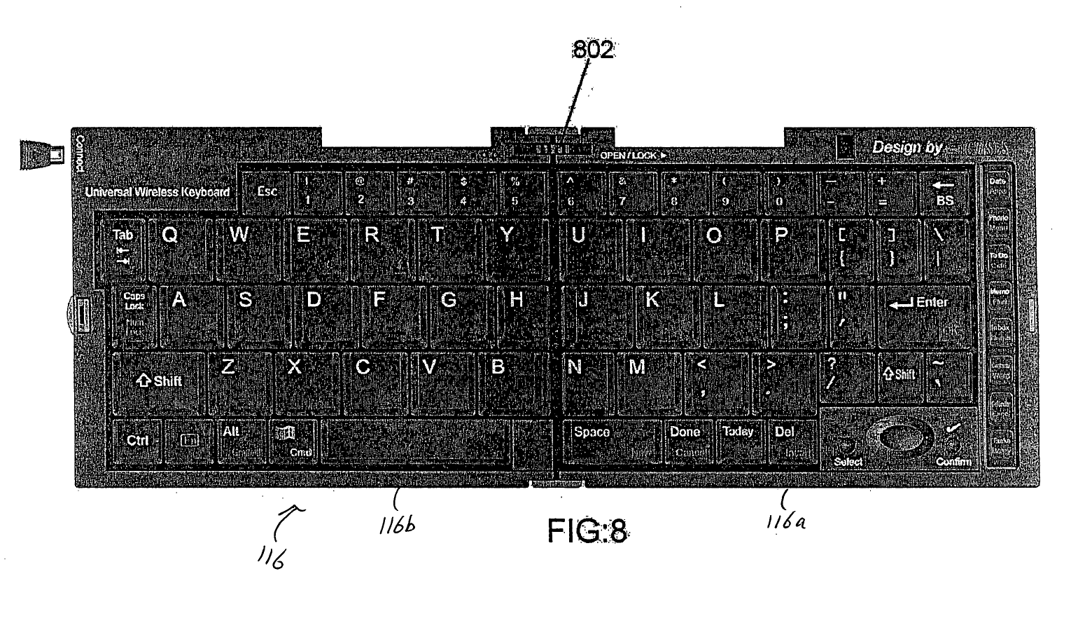

As shown in FIGS. 1A-1D, in one embodiment, keypad 116 includes foldable sections 116a and 116b joined by a central hinge or coupler 118. Alternatively, as shown in FIG. 8, keypad 116 includes latch 802 that, when moved to an “open/lock” position, is capable of locking keypad sections 116a and 116b in a spread-flat position to provide a steady surface to facilitate touch typing, especially on an unsteady base, e.g., one's lap.

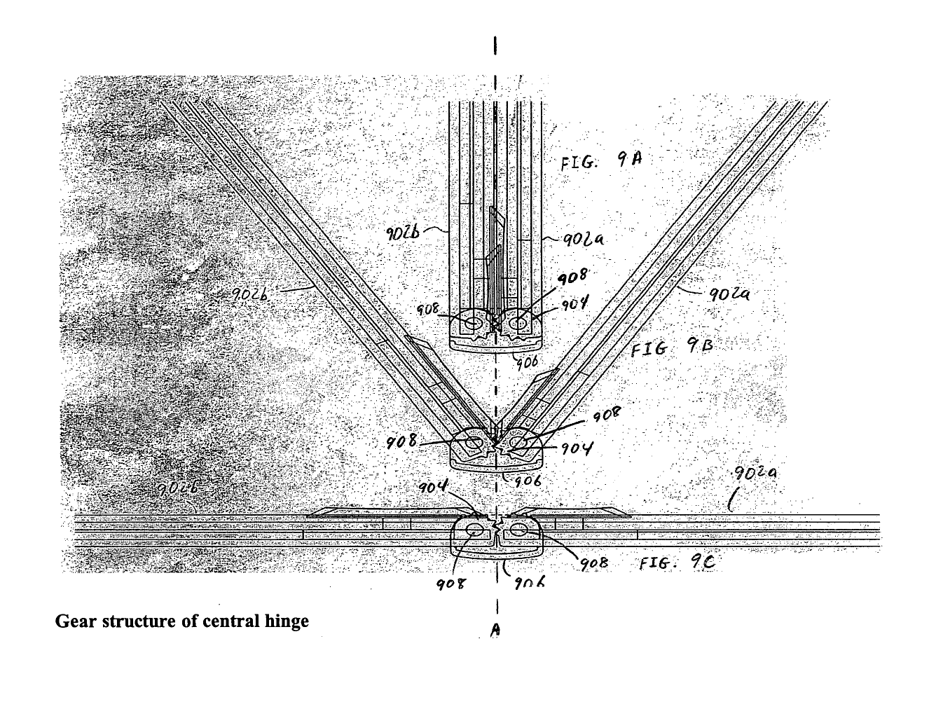

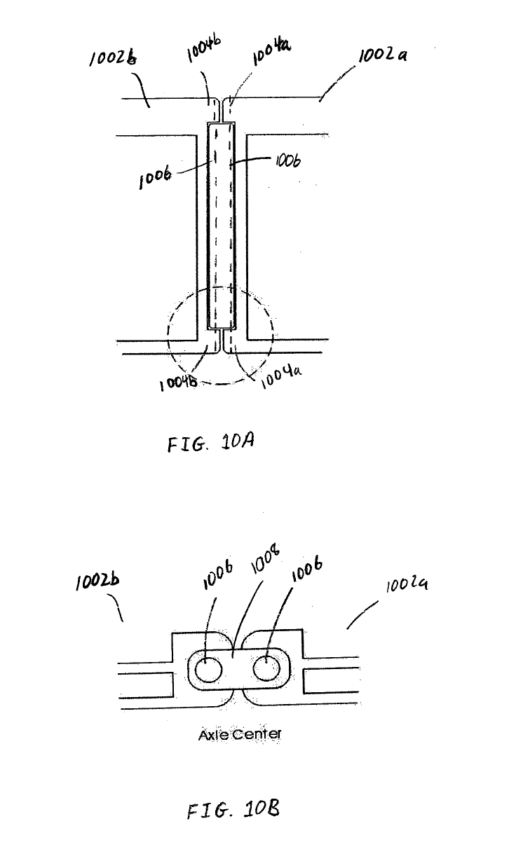

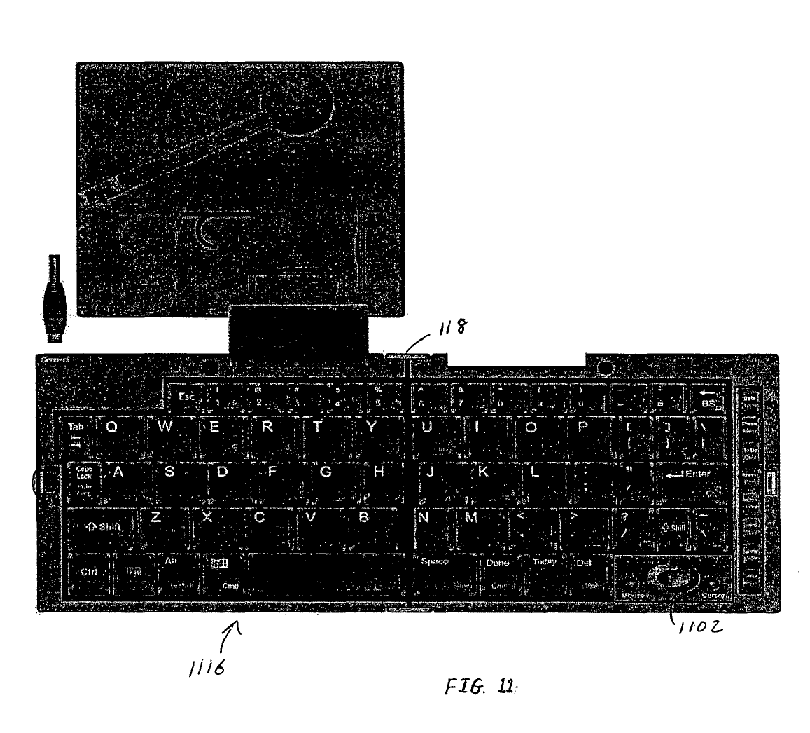

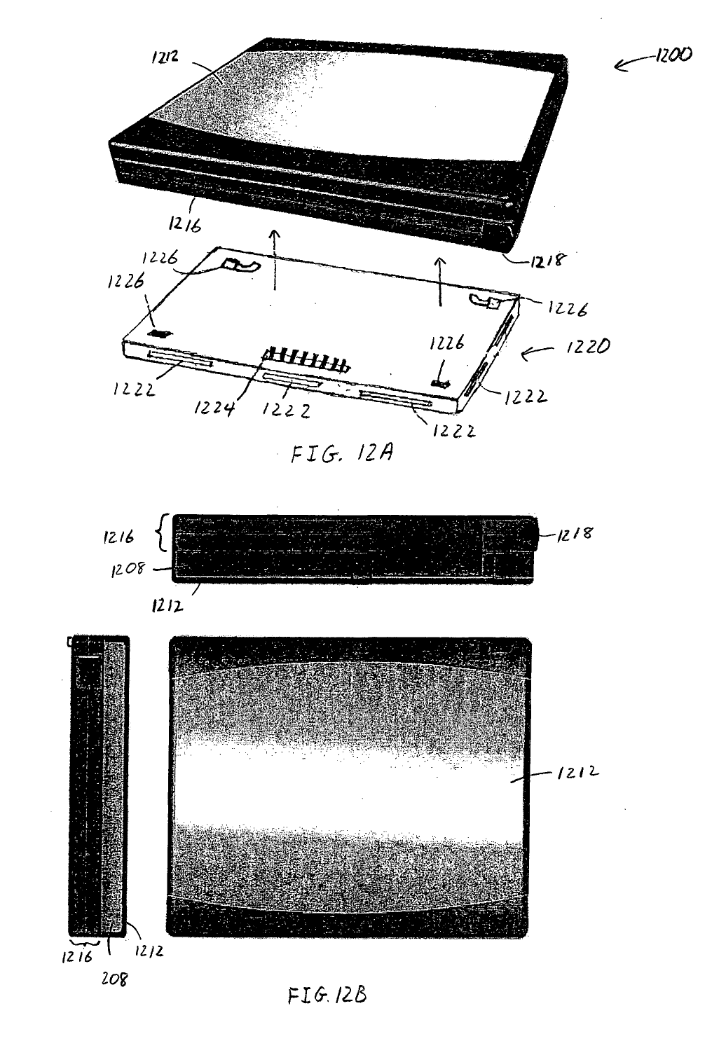

FIGS. 9A-9C and 10A-10B illustrate two central hinge mechanisms that can be used to couple two keypad sections and allow them to fold and unfold properly, in accordance with two embodiments of the present invention. According to one embodiment, shown in FIGS. 9A-9C, keypad section 902a and 902b each include plates 904 provided on opposite sides of the keypad section and connected by rod 908, thus forming a hinge about which plates 904 can rotate. Plates 904 of keypad sections 902a and 902b on each side of the keypad sections are connected by central face plate 906. Plates 904 are each provided teeth-like structures. Central face plate 906 keeps keypad sections 902a and 902b properly aligned by ensuring the teeth on plates 904 on keypad sections 902a and 902b properly mesh during folding or unfolding keypad 902. Central face plate 906 is kept centered at all times during folding or unfolding (i.e., does not slide to either side of center line A), thus allowing for precisely positioned opening and closing of keypad sections 902a and 902b. FIG. 9A shows a side view of a completely folded keyboard device. Keypad sections 902a and 902b are aligned such that plates 904 are properly meshed when folding or unfolding the keypad sections, as shown in FIG. 9B. FIG. 9C shows a completely unfolded keyboard device.

FIGS. 10A-10B illustrate another hinge mechanism that may be used in accordance with another embodiment of the present invention. FIG. 10A shows a top view of keypad sections 1002a and 1002b coupled by a hinge mechanism. Keypad sections 1002a and 1002b each include a pair of arms, designated 1004a for keypad section 1002a and designated 1004b for keypad section 1002b. For each keypad section, the arms are located on opposite side of the keypad section. Between the arms in each pair of arms (i.e., each of arms 1004a and 1004b) is provided a cylindrical through-hole for receiving a pin (designated pin 1006, as shown by dashed lines in FIG. 10A) that runs the length of the through-hole. When the keyboard is unfolded, keypad sections 1002a and 1002b each rotate around the pins 1006, while coupler 1008, shown by a side view in FIG. 10B, couples pins 1006 to keep the keypad sections 1002a and 1002b properly aligned during folding and unfolding. Of course, various other variations of hinge mechanisms, such as a single rod with meshed arms, may also be used within the scope of the present invention.

According to another embodiment of the present invention, FIG. 11 illustrates keypad 1116 on which are provided mouse and cursor controls 1102. A toggle switch or button is provided to activate alternatively keypad 1116 for cursor and mouse functions.

In one embodiment, the keyboard driver software, including software drivers needed for controlling the mouse or cursor functions are loaded into a mobile device from a compact disk through a desktop or notebook computer, connected with the USB or Com port docking station or cradle for the specific mobile device brand and model, or via the IR medium. Alternatively, the keyboard driver software can be pre-loaded by the manufacturer of a mobile device. According to one embodiment of the present invention, the driver software can be provided in one or more removable storage devices (e.g., a flash memory card) that can be plugged into a card reader installed on the universal keyboard. In that embodiment, when the universal keyboard first communicates with a mobile device over a wireless, USB or another serial interface, the universal keyboard queries the make and model of the mobile device and downloads from the removable storage device into the mobile device the appropriate software drivers to control the universal keyboard, including the mouse and cursor functions. Using this arrangement, it is not necessary to download the keyboard software from a desktop or notebook computer to the mobile device, using a docking station or cradle of the mobile device.

As further shown in FIGS. 1A-1D, top cover 112 may be included with universal keyboard 100 to provide a protective top surface and covering to the folded keyboard. In one embodiment, as shown in FIGS. 12A-12B, top cover 1212 folds over docking structure 1208, folded keypad 1216, and central hinge 1218. As discussed above, the IR head assembly can be mounted to either the inner surface or outer surface of the docking structure, and the top cover may be designed to accommodate either configuration.

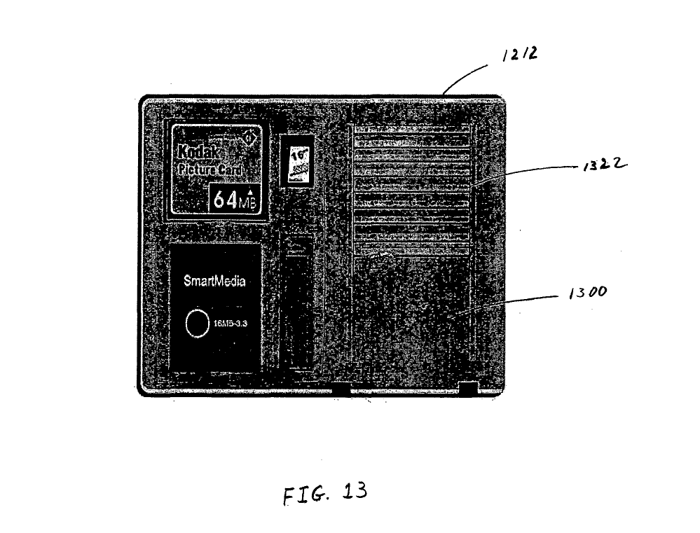

FIG. 13 illustrates inner surface 1300 of top cover 1212, with accommodation of various accessories, according to one embodiment of the present invention. As described above, inner surface of top cover 1212 may include grooves 1322 for holding a stand in place. Furthermore, the inner surface of top cover 1212 may include recesses for accessories, such as memory cards, compact flash (CF) cards, secure digital (SD) cards, multi-media cards (MMC), memory sticks, and PCMCIA (PC) cards.

As shown in FIGS. 1A-1C, curved arrows A-C indicate the manner in which universal keyboard 100 is folded and unfolded, in accordance with an embodiment of the present invention. To fold universal keyboard 100, section 116a first folds over section 116b, as illustrated by arrow A in FIG. 1A. Then, docking structure 108 and top cover 112 may fold over folded key pad section 116a, as shown by arrows B and C. In order to open or unfold universal keyboard 100, docking structure 108 is first unfolded in the manner indicated by arrow A in FIG. 1B. Then, keypad 116a is unfolded away from keypad section 116b in the manner indicated by arrow B in FIG. 1B. Docking structure 108 may then be pulled away from top cover 112 and set at an inclined angle, as shown by arrow C in FIG. 1C. In other embodiments, docking structure 108 and top cover 112 may be coupled so that docking structure 108 and top cover 112 open and close together, automatically moving with one motion by the user.

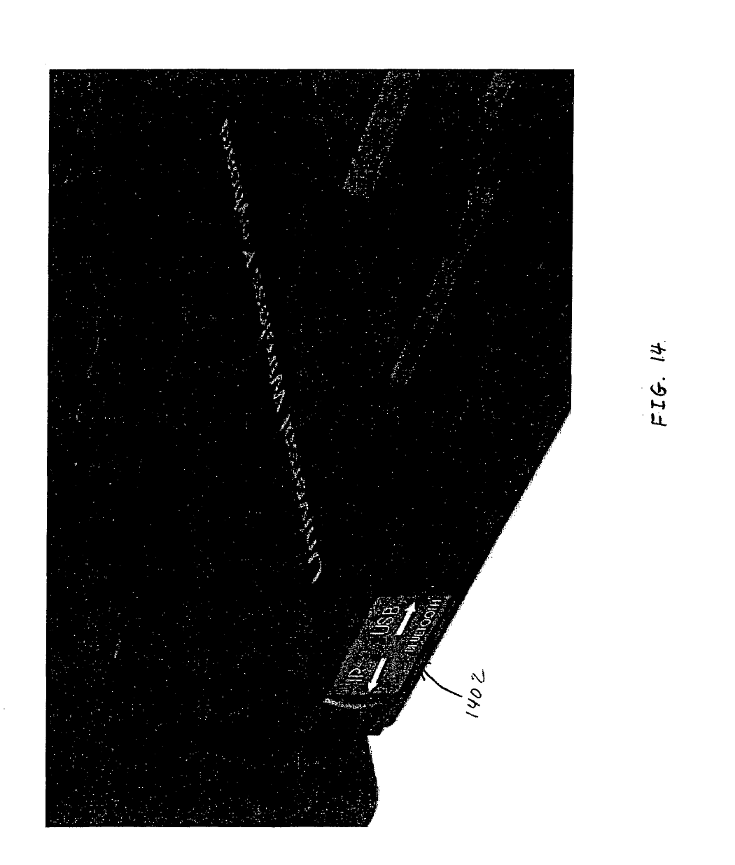

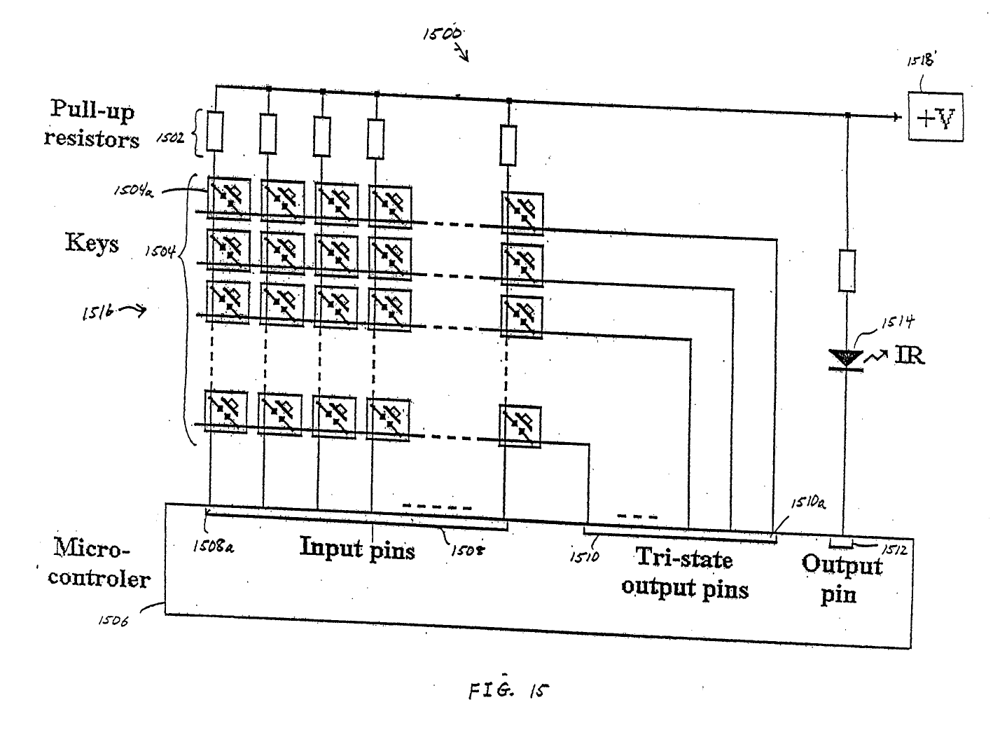

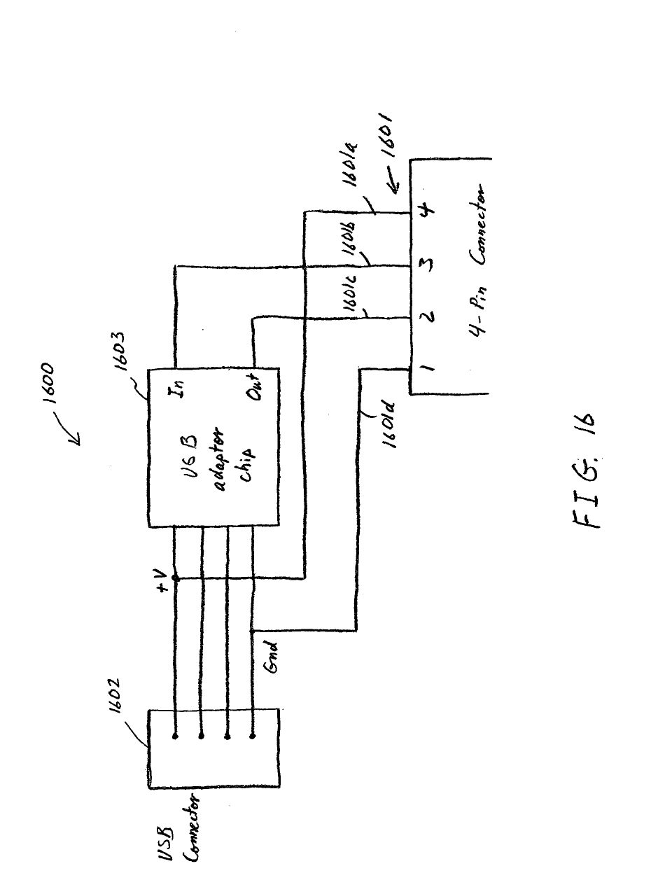

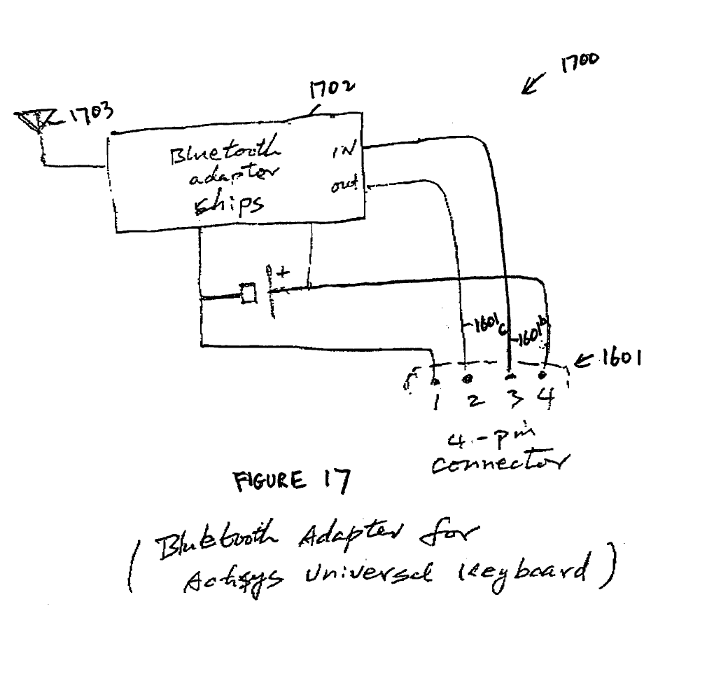

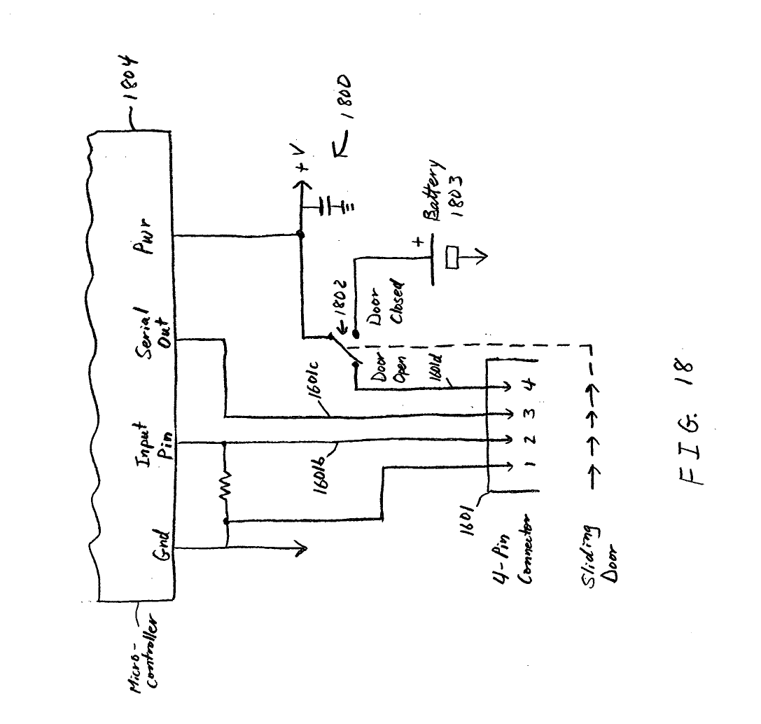

According to another embodiment of the present invention, the universal keyboard includes not only an IR interface but a universal serial bus (USB) interface and a Bluetooth™ interface. As shown in FIG. 14, a universal keyboard may include interface switch 1402 that controls which interface is active. Interface switch 1402 may be set by a user, or by a sensor sensing whether the universal keyboard is coupled to communicate over the USB or Bluetooth™ interface. Driver software for each mobile device type, brand, and model are loaded into the corresponding mobile device to allow the mobile device to communicate with the universal keyboard.

A USB interface applies well to any tablet PC (FIG. 4) or other products equipped with a host-USB port. In one embodiment, the universal keyboard of the present invention has a built-in USB port for connecting an intelligent USB cable to host-USB equipped products.

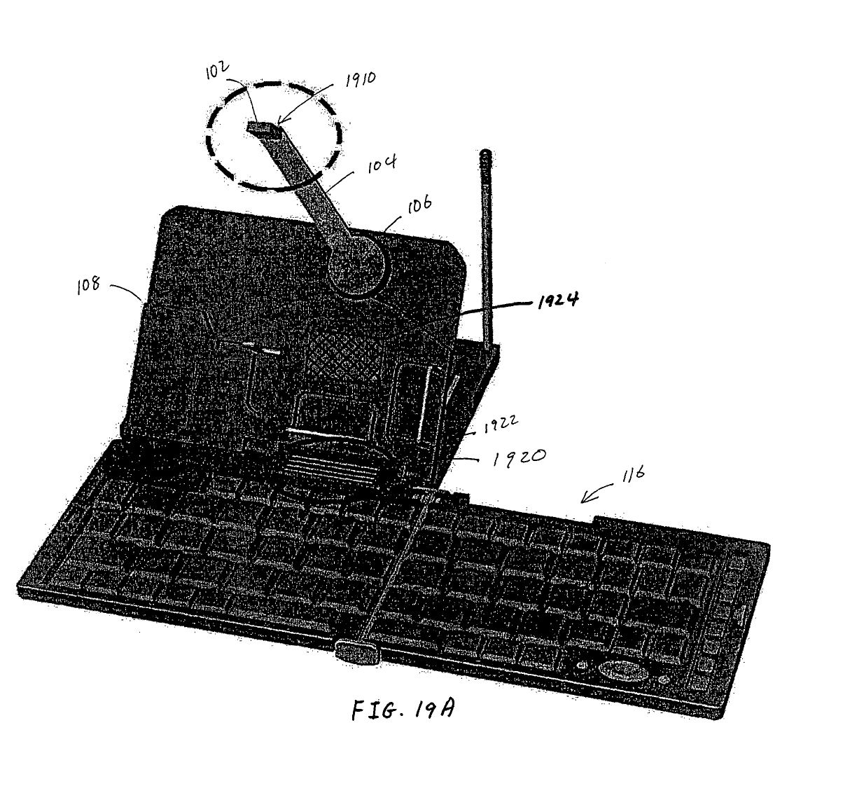

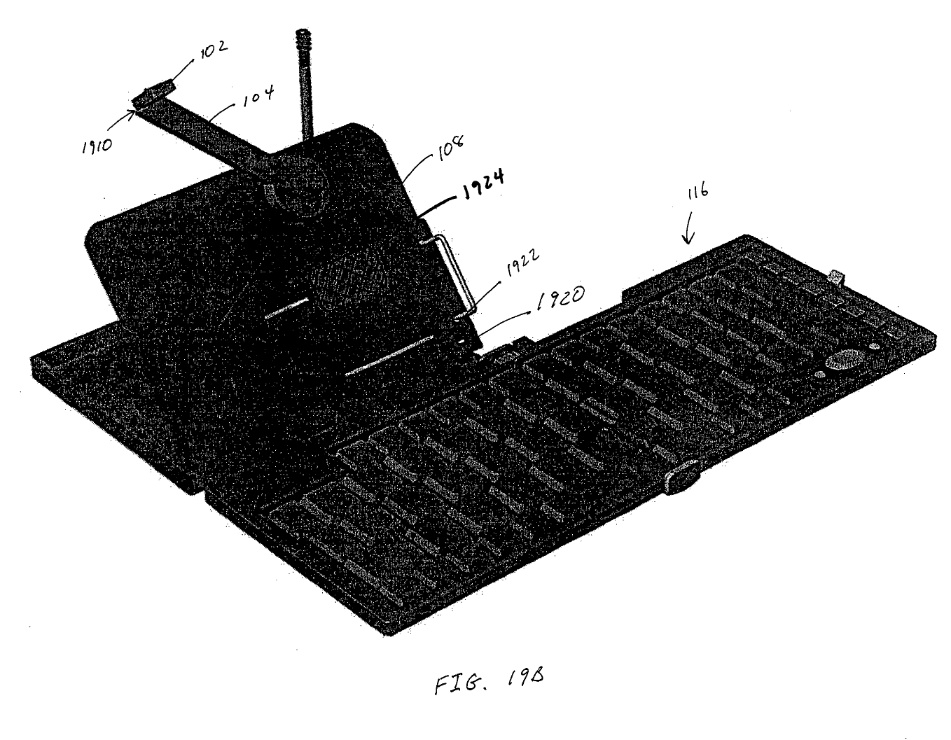

Alternatively, the universal keyboard may provide simply 4-pin connector into which a USB adaptor, a Bluetooth™ adaptor, or another adaptor to another industry standard interface may be provided. FIGS. 16 and 17 show respectively an adaptor for a USB interface and an adaptor for a Bluetooth™ interface. As shown in FIG. 16, adaptor 1600 includes serial port connector 1601 for coupling into a corresponding serial port on universal keyboard 100. Serial port 1601 includes power pin 1601a, input pin 1601b, output pin 1601c and ground pin 1601d. In USB adaptor 1600, the power and ground signals are provided as corresponding power and ground signals in USB connector 1602. USB adaptor chip 1603 (e.g., microcontroller integrated circuit MC68HC908JB8) can be programmed to translate between the signals in input pin 1601b and output pin 1601c and the corresponding signals in a USB Human Interface Device (HID). Similarly, as shown in FIG. 17, Bluetooth™ adaptor integrated circuit (e.g., the BlueCore™ integrated circuit from CSR Limited, Cambridge UK) 1702 translates between the signals in input pin 1601b and output pin 1601c and corresponding signals under the Bluetooth™ standard. In FIG. 17, power is provided by a battery in adaptor 1700, and signals over the Bluetooth™ interface is transmitted and received through antenna 1703.

Unlike PDAs or smart or cellular phones, no driver software is required to operate a tablet PC using a USB interface. Once a cable (e.g., a USB cable) is inserted into the universal keyboard's port (e.g., serial port 1601 described above), a circuitry in the universal keyboard of the present invention automatically senses the inserted cable and turns off electrical current to the IR head, and switches to a serial mode or a USB mode, depending on whether the inserted cable is a serial cable or a USB cable. Under the serial mode or the USB mode, the universal keyboard takes power from the host system (e.g., tablet PC). FIG. 18 shows circuit 1800 suitable for implementing switching between battery power (IR interface) and a serial or USB interface. As shown in FIG. 18, a sensor sensing whether or not a cable is inserted into serial port 1601 controls switch 1802 between a “door open” (i.e., cable inserted, serial or USB port mode) and a “door closed (i.e., no cable inserted, IR interface mode). When switch 1802 is in a “door open” position, power to microcontroller 1804 (i.e., the controller for universal keyboard 100) is provided by power pin 1601d from the external device. When switch 1802 is in the “door closed” position, power to microcontroller 1804 is provided by internal battery 1803.

Alternatively, in one embodiment, to select the IR interface, the user places a switch in the “IR” position. In that position, the switch physically obstructs the USB port. Alternatively, when the switch is placed in the “USB” or “serial” port position, the USB serial port is activated. Such an interface switch prevents the IR port and the USB or serial port to be simultaneously activated. Prevention of simultaneous activation of the IR and USB ports is desirable because, when the IR port is selected, the battery in the keyboard is in the active discharging mode. At the same time, if the USB or serial port is also active, the power from the USB host system force-charges the keyboard battery, and hence causing a possible hazard.

The Bluetooth™ interface can be provided in any PDA, smart or cellular phone, tablet PC, or other mobile product equipped with Bluetooth™ capability, either embedded or externally attached through an adapter or memory card, in one example. When a Bluetooth™ module is plugged into the USB port of the universal keyboard, the keyboard circuitry automatically senses the Bluetooth™ module and turns off electrical current to the IR head and switches to the Bluetooth™ module, according with one embodiment of the present invention.

In other embodiments of the present invention, other wireless communication interfaces beside IR and Bluetooth™ may be included with the universal keyboard, including but not limited to WiFi (Wireless LAN), ZigBee, and radio frequency interfaces, alone or in combination.

In accordance with another embodiment of the present invention, a method for low-power scanning a keyboard is provided utilizing an example of a keyboard circuit shown in FIG. 15. In one embodiment, micro-controller 1506 controls keypad 1516 of universal keyboard 1500 using input pins 1508 (usually 8) to micro-controller 1506 and tri-state output pins 1510 (usually 10 to 19) from micro-controller 1506. Output pin 1512 from micro-controller 1506 is also connected to an infrared light emitting diode (IR LED) 1514, which transmits data to a mobile device through IR radiation. According to the present invention, an appropriate low-power micro-controller (e.g., a 3-volt micro-controller with low standby power consumption) is chosen to control universal keyboard 1500.

Keypad 1516 of universal keyboard 1500 includes keys 1504, each of which is electrically connected to one of input pins 1508 and one of tri-state output pins 1510. Thus, when a user depresses a key, one of the input pins is shorted to one of the output pins. For example, when a user depresses key 1504a, input pin 1508a and output pin 1510a are shorted. This short circuit can be sensed by applying a known voltage briefly and successively on the output pins one at a time, and then sensing the voltage at each of the input pin successively while the voltage is being applied to the output pin. This process for detecting the depressed key is termed “keyboard scanning.” In the embodiment shown in FIG. 15, each of input pins 1508 is connected to a power supply 1518 through individual pull-up resistors 1502. Thus, in the absence of an applied voltage on the output pins, input pins 1508 are pulled up to the power supply voltage level, or “high” level. In the prior art, such pull-up resistors are usually in the tens of kilo-ohms range, so that a few tenths milliampere of current flow through the pull-up resistor when a connected output pin is driven to a “low” level. In the prior art, the pull-up resistor value cannot be increased because stray capacitances in the wires that connect to the keys are of the order of hundreds of picofarads. A higher resistor value would result in an unacceptably large RC time constant. The RC time constant limits how quickly an input pin can return to the high level ready for detecting the next depressed key.

According to the present invention, the firmware of micro-controller 1506 “scans” the keyboard device of universal keyboard 1500 by first driving one of the output pins 1510 to the ground or “low” level, while leaving all other output pins 1510 in a high impedance state. When a short circuit is created due to a depressed key, the input pin corresponding to the depressed key is pulled to a low level by a low voltage on the output pin corresponding to that depressed key.

The firmware of prior art keyboards scan the keyboard at fixed time intervals (e.g., once every 10 to 40 milliseconds). Because of the low resistance in the pull-up resistors, each scan consumes a considerable amount of energy. The longer the scanning interval (i.e., the less frequent the keyboard is scanned), the less energy is used on the average. However, the scanning interval must be short enough to maintain responsiveness to the user's typing. Otherwise, the scanning mechanism may miss some of the keys depressed by a fast typist.

According to one embodiment of the present invention, rather than using a fixed scanning interval, an adaptive scanning interval is used. The scanning interval according to the present invention is determined by the frequency in which keys 1504 are depressed and released. When keys 1504 are depressed and released quickly, the firmware shortens its scanning interval so that it does not miss any user action. When the firmware senses that keys 1504 are depressed and released less frequently, it lengthens the scanning interval to conserve energy.

In accordance with another embodiment of the present invention, the value of pull-up resistors 1502 is increased above 100 kilo-ohms, preferably in the multiple mega-ohms range (e.g., 1 to 100 mega-ohms), thereby reducing the current consumption during scanning from tenths of milliamperes to microamperes. A slow recovery time is avoided by a special step in the scanning process. Each time a depressed key is detected, and before the corresponding output pin is put back into a high impedance state, the output pin is momentarily driven high to recharge the stray capacitance of the wire. The slow recharge through the large pull-up resistor is therefore avoided. Thus, even though a much larger pull-up resistor value than that in the prior art is used, the universal keyboard of the present invention does not result in a keyboard with slower responsiveness.

Accordingly, the low-power keyboard scanning method in accordance with the present invention is more energy efficient than prior art keyboards. The low-power keyboard scanning method of the present invention allows keyboards of the present invention to use two low-cost CR2032 coin batteries for up to six months under a typical usage of two hours of continuous typing per day. Prior art keyboards required larger-capacity batteries or a greater number of batteries that were capable of a higher electrical current and a higher energy capacity. It is evident that other types of batteries could be used in accordance with the present invention, such as solar-powered or rechargeable batteries.

In accordance with another embodiment of the present invention, a wireless data transmission method is provided that advantageously sends “transmission code” as described in greater detail below. Each key of the keypad is assigned a keycode from hexadecimal (“hex”) 01 to hex 7E, allowing for up to 126 keycodes in one example using the hexadecimal numbering system.

When a key is pressed (“make”), four data segments (e.g., four bytes) are transmitted via infrared or other wireless method. A first data segment (e.g., a first byte) of a transmission is a constant, for example hex FF, that indicates the first of the four data segments representing the pressed key.

A second data segment (e.g., a second byte) is the keycode assigned to the pressed key of the keypad (hex 01 to hex 7E). Each key in the keypad is assigned a unique keycode.

A third data segment (e.g., a third byte) is a code for the current context (e.g., a “context” key, if any, which is held down, a “lock” key which is in effect, or a combination of a context key and a lock key). For an 8-bit data segment, for example, up to 255 different contexts can be represented.

A fourth data segment (e.g., a fourth byte) is used for an error check of the second and third data segments (e.g., the second and third bytes). In one example, a cyclic redundancy checksum (e.g., CRC8, CRC16) is used to detect an error in the transmission and storage of data.

When a key is released (“break”), two data segments (e.g., 2 bytes) are transmitted. In one example, the first data segment (e.g., a first byte) is a constant (e.g., hex FF) to indicate the first of these two data segments.

In one example, the second data segment (e.g., a second byte) is hex 80 if the last pressed key is being released (i.e., all pressed keys are released), and is hex 80 plus a keycode if there is still at least one key that is not yet released. The keycode added to hex 80 would correlate to the single key being released.

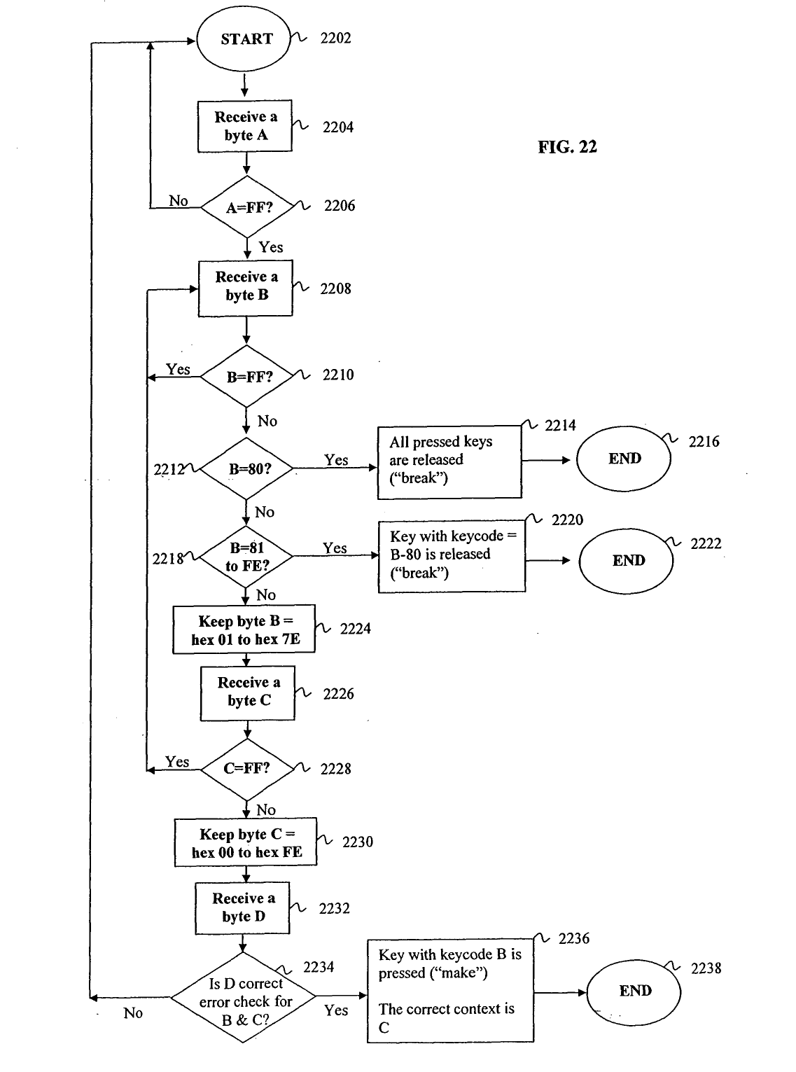

FIG. 22 illustrates a flowchart of the wireless data transmission method in accordance with an embodiment of the present invention. Software inside a computer or microprocessor (e.g., in the mobile device) will receive the “transmission code” described above to advantageously check for transmission errors and avoid displaying illegitimate characters.

At step 2202, the computer waits for any incoming transmission. At step 2204, the computer receives a first data segment, for example a byte A. The computer checks whether byte A is hex FF at step 2206. If byte A is hex FF, the computer goes to step 2208 to receive a second data segment, for example a byte B. If byte A is not hex FF, the computer goes back to step 2202 to wait for an incoming transmission and begin the cycle again.

At step 2210, the computer checks whether byte B is hex FF. If byte B is hex FF, the computer goes back to step 2208 to receive another byte.

At step 2212, the computer checks whether byte B is hex 80. If byte B is hex 80, then in step 2214, the computer translates the transmission as “break” of all keys that are currently held down and the transmission code is interpreted to end at step 2216.

If byte B is not hex 80, then in step 2218, the computer checks whether byte B is between hex 81 and hex FE. If byte B is between hex 81 and hex FE, then in step 2220, the computer translates the transmission as “break” of a single key. The key with a keycode equal to byte B minus hex 80 is determined to be the key that was released and the transmission code is interpreted to end at step 2222.

If byte B is not between hex 81 and hex FE, then at step 2224, the computer keeps the second data segment, for example byte B having a value between hex 01 and hex 7E, as a potential “make”. The computer moves to step 2226.

At step 2226, the computer receives a third data segment, for example a byte C. At step 2228, the computer checks whether byte C is hex FF. If byte C is hex FF, the computer discards the potential “make” and goes back to step 2208 to receive a second data segment.

If byte C does not have a value of hex FF, then at step 2230, the computer keeps the third data segment, for example byte C having a value between hex 00 and hex FE, as a potential context code. The computer moves to step 2232.

At step 2232, the computer receives a fourth data segment, for example a byte D, as an error check of the second and third data segments (e.g., bytes B and C).

The computer moves to step 2234, to conduct an error check with the potential “make” (e.g., byte B) and potential context code (e.g., byte C). If an error is determined, the computer ignores the transmission and moves to step 2202 to begin the cycle again. If no error is determined, the computer moves to step 2236 to translate both the “make” and context and the transmission code is interpreted to end at step 2238.

In accordance with another embodiment of the present invention, a method and structure are provided for downloading software from a universal keyboard to a mobile device in communication with the universal keyboard. Software is loaded into mobile devices by removable storage media, such as compact flash cards, security digital cards, and the like, which are capable of being accessed by the universal keyboard of the present invention through integrated or external access devices. An example of an access device module including multiple access devices is illustrated in FIG. 12A and described in greater detail below. However, it should be understood that the universal keyboard may be manufactured with integrated access devices and does not require a storage access device to be external or separately attachable.

FIG. 12A shows one example of a storage access device module 1220 that can be operably connected to universal keyboard 1200 in accordance with the present invention. In this example, access device module 1220 includes multiple storage access devices 1222 for accessing removable storage media such as those shown in FIG. 13. In one example, access devices 1222 are card slots that can read and write onto storage media of various standards, such as memory cards, compact flash (CF) cards, secure digital (SD) cards, multi-media cards (MMC), memory sticks, and PCMCIA (PC) cards. A recessed multi-pin connector 1224 on module 1220 connects with a mating multi-pin connector (not shown) on the underside of universal keyboard 1200 to provide electrical connection between universal keyboard 1200 and module 1220. A locking mechanism 1226 connects with a mating locking mechanism (not shown) on the underside of universal keyboard 1220 to provide physical connection of module 1220 to the bottom of universal keyboard 1200.

The software in the storage medium queries and acquires specific mobile device identification information (e.g., brand and model), and automatically selects and downloads the appropriate software from the storage medium to the mobile device using a communication interface, such as a USB interface, or a wireless communication interface, such as infra-red communication interface, a Bluetooth™ interface, a WiFi (Wireless LAN) interface, a radio frequency interface, and/or a ZigBee interface. In one example, a two-way IR head including an IR receiver and transmitter are used for querying and downloading data.

Utilizing such a software transmission method, keys of the universal keyboard can be customized by software in a storage medium to program special function keys, including multimedia control keys of a specific mobile device. For example, left and right arrow keys may be programmed to have forward and rewind functionality for an audio player. Software in the storage medium can query and acquire the control codes of special function and multimedia control keys for the specific mobile device and then automatically customize programmable keys of the universal keyboard in accordance with the present invention.

In another embodiment, such a software transmission method allows for audio, video, and multimedia files to be acquired from the universal keyboard and executed on a mobile device. In one example, a video or other multimedia file with display-format conversion tables for various mobile devices that are pre-stored in the removable or fixed storage medium of universal keyboard, can be downloaded to a mobile device in communication with the universal keyboard. The video or other multimedia file can be executed and displayed on the screen of the mobile device while streaming data or after complete downloading. This method is advantageous for mobile devices which may not have an access device for removable storage media or insufficient memory to execute large multimedia files. It is evident that display format conversion for a specific mobile device may be automatically selected by software in the storage medium.

In accordance with another embodiment of the present invention, a method and structure are provided for interfacing with a mobile device in communication with the universal keyboard. In one example, the universal keyboard includes multiple slots or multiple storage access devices for accessing storage media of different standards. Accessing includes retrieving data from and writing data to the storage medium of the access device. A mobile device is docked to be in communication with the universal keyboard and selected data from the mobile device is written onto the storage media in communication with the universal keyboard. Thus, the data from the mobile device can be transferred to different types of storage media, in different data formats, and for use in other different mobile or non-mobile devices.

In another example, the universal keyboard includes multiple communication interfaces for concurrently accessing multiple mobile devices. Data synchronization then occurs between the multiple mobile devices. In both of these examples, the keyboard has available synchronization and format conversion software pre-stored in its storage medium.

The above-described embodiments of the present invention are merely meant to be illustrative and not limiting. Various changes and modifications may be made within the scope of this invention. Therefore, the appended claims encompass all such changes and modifications.

What is claimed is:

1. A wireless data transmission method, comprising:
providing a first data segment;
verifying that the first data segment includes a desired constant;
providing a variable second data segment that indicates making a key or breaking a key;
providing a third data segment to indicate a context code; and
providing a fourth data segment as an error check of the second and third data segments.

2. The method of claim 1, wherein the desired constant of the first data segment is hexadecimal FF.

3. The method of claim 1, wherein the second data segment indicates releasing all pressed keys or releasing a single pressed key.

4. The method of claim 1, wherein the second data segment includes a value of hexadecimal 80.

5. The method of claim 1, wherein the second data segment is between hexadecimal 81 and hexadecimal FE.

6. The method of claim 1, wherein the second data segment is between hexadecimal 01 and hexadecimal 7E.

7. The method of claim 1, wherein the third data segment is between hexadecimal 00 and hexadecimal FE.

8. The method of claim 1, wherein the fourth data segment is used for a cyclic redundancy checksum algorithm.

9. A method for downloading data through a keyboard, comprising:
providing in the keyboard a communication interface for establishing a communication link with a mobile device;
providing a storage access device for retrieving data from a storage medium; and
providing a controller coupled to the communication interface and the storage access device, the controller being programmed to:
using the communication interface, retrieve identification information from a mobile device;
according to the identification information, retrieve from the storage medium a program code; and
using the communication interface, transmit to the mobile device the program code.

10. The method of claim 9, wherein the storage medium is removable.

11. The method of claim 9, wherein the communication interface comprises a USB interface.

12. The method of claim 9, wherein the communication interface comprises a wireless interface.

13. The method of claim 12, wherein the wireless interface is selected from the group consisting of an infrared communication interface, a Bluetooth™ interface, a WiFi (Wireless LAN) interface, a radio frequency interface, and a ZigBee interface.

14. The method of claim 9, wherein the program code includes software for programming special function keys when operating the keyboard.

15. The method of claim 14, wherein the special function keys include multimedia control keys for the mobile device.

16. The method of claim 14, wherein the software for programming special function keys automatically customizes programmable keys of the keyboard.

17. The method of claim 9, wherein the program code includes keyboard software, video, audio, or multimedia files.

18. The method of claim 9, wherein the program code includes display-format conversion tables for various mobile devices to display video on a screen of the mobile device.

19. The method of claim 18, wherein a display-format conversion for a specific mobile device is automatically selected.

20. The method of claim 9, wherein the program code is selected from the group consisting of application software, data synchronization software, and data format conversion software.

21. The method of claim 9, wherein the mobile device executes the transmitted program code, and displays, if needed, the transmitted content.

22. A method for interfacing with a mobile device in communication with a keyboard, comprising:
providing in the keyboard a communication interface for establishing a communication link with a mobile device;
providing a plurality of storage access devices for writing data to storage media; and
providing a controller coupled to the communication interface and the plurality of storage access devices, the controller being programmed to:
using the communication interface, retrieve from the mobile device data to be synchronized; and
using the controller, send the data to be synchronized to the plurality of storage access devices.

23. The method of claim 22, wherein the communication interface comprises a USB interface.

24. The method of claim 22, wherein the communication interface comprises a wireless interface.

25. The method of claim 24, wherein the wireless interface is selected from the group consisting of an infrared communication interface, a Bluetooth™ interface, a WiFi (Wireless LAN) interface, a radio frequency interface, and a ZigBee interface.

26. A method for interfacing between mobile devices in communication with a keyboard, comprising:
providing in the keyboard a plurality of communication interfaces for establishing a communication link with a plurality of mobile devices; and
providing a controller coupled to the plurality of communication interfaces, the controller being programmed to synchronize data between the plurality of mobile devices using the plurality of communication interfaces.

27. The method of claim 26, wherein a communication interface of the plurality of communication interfaces comprises a USB interface.

28. The method of claim 26, wherein a communication interface of the plurality of communication interfaces comprises a wireless interface.

29. The method of claim 28, wherein the wireless interface is selected from the group consisting of an infrared communication interface, a Bluetooth™ interface, a WiFi (Wireless LAN) interface, a radio frequency interface, and a ZigBee interface.

30. A universal keyboard, comprising:
a docking structure for accommodating a mobile device;
an infrared (IR) head clamp for receiving and transmitting data over a wireless link, the IR head clamp capable of being positioned over an IR interface of the mobile device;
a keypad that is physically coupled to the docking structure, and providing electrical signals representing the keys on the keypad that are depressed by an external agent; and
a controller circuit receiving the electrical signals and converting the electrical signals into data for transmission by the IR head clamp over the wireless link.

31. The universal keyboard of claim 30, wherein the IR head clamp includes an IR head and a clamp body.

32. The universal keyboard of claim 31, wherein the IR head includes a light emitting diode (LED).

33. The universal keyboard of claim 31, wherein the IR head includes an IR transceiver, an LED emitter, and a PIN diode detector.

34. The universal keyboard of claim 31, wherein the IR head is operably coupled to the clamp body by a universal joint.

35. The universal keyboard of claim 31, wherein the IR head is operably coupled to the clamp body by one or more rotating joints.

36. The universal keyboard of claim 31, wherein the clamp body is capable of being flexed open and closed.

37. The universal keyboard of claim 31, wherein the clamp body includes a first member coupled to a second member, the first member and the second member capable of being moved apart and together along a joint.

38. A universal keyboard, comprising:
a docking structure for accommodating a mobile device;
an arm having a first end mounted on the docking structure at one end by a connector, and having a second freely movable end, such that the second freely movable end of the arm traces an arc centered about the connector over a predetermined range of angles;
an infrared (IR) head mounted on the freely movable end of the arm for receiving and transmitting data over a wireless link;
a keypad that is physically coupled to the docking structure, and providing electrical signals representing the keys on the keypad that are depressed by an external agent; and
a controller circuit receiving the electrical signals and converting the electrical signals into data for transmission by the IR head over the wireless link.

39. The universal keyboard of claim 38, wherein the connector includes a gear structure with teeth and a separate teeth structure.

40. The universal keyboard of claim 38, wherein the connector includes an electrical wire in the form of a stretchable coil.

41. The universal keyboard of claim 38, wherein the IR head is capable of bending and/or rotating in a plurality of angles relative to the arm.

42. The universal keyboard of claim 38, wherein the IR head includes a wide-angle LED.

43. The universal keyboard of claim 38, wherein the IR head includes an IR transceiver, an LED emitter, and a PIN diode detector.

44. The universal keyboard of claim 38, wherein the IR head is capable of receiving and sending data at a high rate of speed.

45. The universal keyboard of claim 38, wherein the IR head is powered by a battery that can be solar-powered and/or recharged.

46. The universal keyboard of claim 38, wherein the keys of the keyboard are voice-activated.

47. The universal keyboard of claim 38, further comprising an anti-skid surface for mounting the mobile device, the surface being located between the docking structure and the keypad.

48. The universal keyboard of claim 38, further comprising an anti-skid surface on the docking structure for mounting the mobile device.

49. The universal keyboard of claim 38, further comprising movable holders mounted on the docking structure to accommodate any of a plurality of mobile devices, wherein the holders are made of a rubber material or a metallic material coated with anti-skid material.

50. A keyboard, comprising:
a communication interface for establishing a communication link with a mobile device;
a storage access device for retrieving data from and writing data to a storage medium; and
a controller coupled to the communication interface and the storage access device, the controller being programmed to:
using the communication interface, retrieve identification information from the mobile device;
according to the identification information, retrieve from the storage medium a program code; and
using the communication interface, transmit to the mobile device the program code.

51. The keyboard as in claim 50, wherein the storage access device is a detachable module.

52. The keyboard as in claim 51, wherein the detachable module includes a plurality of storage access devices.

53. The keyboard as in claim 50, wherein the storage medium is removable.

54. The keyboard as in claim 50, wherein the communication interface comprises a USB interface.

55. The keyboard as in claim 50, wherein the communication interface comprises a wireless interface.

56. The keyboard as in claim 55, wherein the wireless interface is selected from the group consisting of an infrared communication interface, a Bluetooth™ interface, a WiFi (Wireless LAN) interface, a radio frequency interface, and a ZigBee interface.

57. The keyboard as in claim 50, wherein the program code includes data synchronization software.

58. The keyboard as in claim 50, wherein the program code includes data format conversion software.

59. The keyboard as in claim 50, wherein the program code includes software for operating the keyboard keys, or for programming special function keys when operating the keyboard.

60. The keyboard as in claim 50, wherein the program code includes video, audio, or multimedia files.

61. The keyboard as in claim 50, further comprising a plurality of access devices for concurrent access to a plurality of storage media.

62. The keyboard as in claim 61, wherein the controller is further programmed to:
using the communication interface, retrieve from the mobile device data to be synchronized; and
using the controller, send the data to be synchronized to the plurality of storage access devices.

63. The keyboard as in claim 50, further comprising a plurality of communication interfaces for concurrent access to a plurality of mobile devices.

64. The keyboard as in claim 63, wherein the controller is further programmed to synchronize data between the plurality of mobile devices using the plurality of communication interfaces.
